(19) United States
(12) Patent Application Publication
(10) Pub. No.: US 2026/0293393 A1
(43) Pub. Date: Sep. 24, 2026

(54) MICRO-LED WITH DUMMY LIGHT-EMITTING MESA AND MICRO-LED CHIP

(71) Applicant: Hue Inc., Shanghai (CN)

(72) Inventors: Feng Feng, Shanghai (CN); Jian Guo, Shanghai (CN)

(73) Assignee: Hue Inc., Shanghai (CN)

(21) Appl. No.: 19/458,889

(22) Filed: Jan. 25, 2026

(30) Foreign Application Priority Data
Jan. 26, 2025 (CN) 202510124075.9

(51) Int. Cl. H10H 29/24; H10H 20/819; H10H 20/833; H10H 20/856; H10H 29/80

(52) U.S. Cl. CPC H10H 29/24; H10H 20/819; H10H 20/833; H10H 20/856; H10H 29/842

(57) ABSTRACT

The present invention provides an epitaxial wafer with a dummy light-emitting mesa, including: a temporary substrate; a light-emitting mesa arranged on the temporary substrate, which includes: a bottom transparent conductive layer arranged on a side of the light-emitting mesa facing away from the temporary substrate; a first epitaxial layer arranged between the bottom transparent conductive layer and a light-emitting layer; a light-emitting layer arranged between the first epitaxial layer and a second epitaxial layer and configured to emit light; and a second epitaxial layer arranged on a side of the light-emitting mesa facing the temporary substrate, wherein the area of the upper surface of the light-emitting mesa facing the temporary substrate is greater than the area of the lower surface facing away from the temporary substrate.

### CROSS-REFERENCE TO RELATED APPLICATION

This application claims the priority benefit of China application serial no. 202510124075.9, filed on Jan. 26, 2025. The entirety of the above-mentioned patent application is hereby incorporated by reference herein and made a part of this specification.

### BACKGROUND

### Technical Field

The present invention generally relates to the field of micro-LEDs, and more specifically relates to a micro-LED with a dummy light-emitting mesa and micro-LED chip.

### Description of Related Art

Micro light-emitting diode (Micro-LED) is a new type LED structure obtained by thin-filming, miniaturizing, and arraying the original LED structure, which integrates the arrayed micro level micro LEDs on an active addressing drive panel to achieve the lighting and individual control of the micro-LEDs, thereby outputting the desired display image. The core structure of the micro-LED is a light-emitting mesa, which includes a PN junction diode, and the PN junction diode is composed of direct-bandgap semiconductor material. When the upper and lower electrodes apply a forward bias voltage to the micro-LED to allow current to pass through, electrons and holes recombine in the active area, and meanwhile emit monochromatic light photons.

The light-emitting mesa of the micro-LED includes a normally arranged trapezoidal light-emitting mesa and an upside-down arranged trapezoidal light-emitting mesa, wherein the upper surface of the normally arranged trapezoidal light-emitting mesa is smaller than the lower surface, while the case for the upside-down arranged trapezoidal light-emitting mesa is exactly the opposite. Currently, a difficulty in manufacturing micro-LEDs based on upside-down arranged trapezoidal light-emitting mesas on epitaxial wafers lies in that, when an insulating layer is deposited on the epitaxial wafer to cover the light-emitting mesa, the coated insulating layer is prone to delamination or voids due to the shear stress generated parallel to the epitaxial wafer. Epitaxial wafers with delamination or voids require multiple rework and leveling processes such as chemical mechanical polishing (CMP), which increases the complexity of the process and brings certain uncertainty to product quality.

### SUMMARY

Starting from the prior art, the task of the present invention is to provide an epitaxial wafer with a dummy light-emitting mesa and a micro-LED chip, and through the epitaxial wafer or the micro-LED chip, the risks of delamination or void formation between the insulating layer and the light-emitting mesa can be significantly reduced.

In a first aspect of the present invention, the aforementioned task is solved by a micro-LED with a dummy light-emitting mesa, which includes:
a plurality of light-emitting mesas, each light-emitting mesa including:
a bottom transparent conductive layer;
a light-emitting layer; and
a first epitaxial layer arranged between the bottom transparent conductive layer and a light-emitting layer;
a second epitaxial layer arranged on the light-emitting layer, where the light-emitting layer arranged between the first epitaxial layer and the second epitaxial layer and configured to emit light, and an area of the upper surface of the light-emitting mesa close to the second epitaxial layer is greater than an area of a lower surface close to the first epitaxial layer; and
a passivation layer covering a lower surface and a side surface of the light-emitting mesa, where the light-emitting mesa includes at least one first light-emitting mesa and at least one dummy light-emitting mesa, where the passivation layer on the at least one first light-emitting mesa has at least one notch to expose the bottom transparent conductive layer, and the passivation layer on the at least one dummy light-emitting mesa has no notch.

In one embodiment, a depth of the dummy light-emitting mesa is different from a depth of the first light-emitting mesa; and/or
a diameter of the upper surface of the dummy light-emitting mesa is different from a diameter of the upper surface of the first light-emitting mesa; and/or
a diameter of the lower surface of the dummy light-emitting mesa is different from a diameter of the lower surface of the first light-emitting mesa; and/or
a spacing between the dummy light-emitting mesas is different from a spacing between the first light-emitting mesas.

In one embodiment, where:
the depth of the dummy light-emitting mesa is the same as the depth of the first light-emitting mesa; and/or
the diameter of the upper surface of the dummy light-emitting mesa is the same as the diameter of the upper surface of the first light-emitting mesa; and/or
the diameter of the lower surface of the dummy light-emitting mesa is the same as the diameter of the lower surface of the first light-emitting mesa; and/or
the spacing between the dummy light-emitting mesas is the same as the spacing between the first light-emitting mesas.

In one embodiment, the micro-LED further includes:
a substrate supporting the light-emitting mesas.

In one embodiment, the micro-LED further includes:
dicing lanes configured to identify boundaries between adjacent micro-LED chips, where the dicing lanes are arranged between the dummy light-emitting mesas.

In one embodiment, a buffer layer is comprised,
a thickness of the buffer layer is 4000 to 8000 angstroms; and/or
a thickness of the first epitaxial layer is 2500 to 3500 angstroms; and/or
a thickness of the light-emitting layer is 2000 to 4000 angstroms; and/or
a thickness of the second epitaxial layer is 4000 to 5000 angstroms; and/or
a thickness of the bottom transparent conductive layer is 800 to 1500 μm; and/or
a thickness of the passivation layer is 800 angstroms to 1800 angstroms.

In one embodiment, the material of the substrate is selected from a group that includes the following items: silicon (Si), silicon dioxide (SiO₂), silicon nitride (Si₃N₄), silicon carbide (SiC), gallium nitride (GaN), glass, aluminum nitride (AlN), sapphire (α-Al₂O₃), and germanium (Ge).

In one embodiment, a number of dummy light-emitting mesas accounts for 40% to 50% of the total number of light-emitting mesas.

In one embodiment, a diameter of the lower surface of the light-emitting mesa is 0.8 to 1.2 μm; and/or
a diameter of the upper surface of the light-emitting mesa is 1.4 to 1.8 μm; and/or
a height of the light-emitting mesa is 0.3 to 0.7 μm.

In one embodiment, the second epitaxial layer includes:
a step portion, which is in electrical contact with the light-emitting layer; and
a base portion extending from the step portion toward two sides of the step portion.

In one embodiment, the base portions of adjacent light-emitting mesas are connected with each other.

In one embodiment, a thickness of the step portion is: 400 nm to 800 nm; and/or
a thickness of the base portion is 4 to 4.4 μm.

In one embodiment, the passivation layer covers the side surface of the step portion and the surface of the base portion.

In one embodiment, the micro-LED further includes:
a reflective mirror layer arranged to surround the first light-emitting mesa;
at least one drive circuit having a metal layer, a plurality of through-hole contact portions are arranged on the at least one drive circuit, where the plurality of through-hole contact portions are electrically connected with the metal layer, and an area of the micro-LED array is bonded onto the drive circuit through a bottom conductive bonding layer, where the at least one drive circuit further comprises a wiring stacked layer below the metal layer, the wiring stacked layer configured to lead out a first electrode;
an insulating layer configured to accommodate the first light-emitting mesa, the dummy light-emitting mesa, and the plurality of through-hole contact portions;
a first electrode electrically connected with the plurality of through-hole contact portions
a top transparent conductive layer arranged on the surface of the passivation layer and in electrical contact with the second epitaxial layer; and
a second electrode arranged on the surface of the top transparent conductive layer.

In order to achieve the above objects, the present invention further provides a micro-LED chip with a dummy light-emitting mesa, which includes:
a light-emitting area including a plurality of first light-emitting mesas, the first light-emitting mesas are configured to emit light; and
a non-light-emitting area adjacent to the light-emitting area and including a plurality of dummy light-emitting mesas, the dummy light-emitting mesas configured to not emit light.

In one embodiment, the proportion of the light-emitting area in the micro-LED chip is 50% to 60%; and/or
the proportion of non-light-emitting area in the micro-LED chip is 40% to 50%.

In one embodiment, both the first light-emitting mesa and the dummy light-emitting mesa include:
a bottom transparent conductive layer facing the light extraction side;
a light-emitting layer;
a first epitaxial layer arranged between the bottom transparent conductive layer and the light-emitting layer; and
a second epitaxial layer facing away from the light extraction side, where the light-emitting layer is arranged between the first epitaxial layer and the second epitaxial layer and configured to emit light, and an area of the upper surface of the light-emitting mesa facing the light extraction side is greater than the area of the lower surface facing away from the light extraction side.

In one embodiment, the first light-emitting mesa has the same dimensions as the dummy light-emitting mesa, the dimensions including: upper surface dimension, lower surface dimension, and the height of the light-emitting mesa.

In one embodiment, a diameter of the lower surface of the first light-emitting mesa is 0.8 to 1.2 μm; and/or
a diameter of the upper surface of the first light-emitting mesa is 1.4 to 1.8 μm; and/or
a height of the first light-emitting mesa is 0.3 to 0.7 μm.

In one embodiment, the light-emitting area further includes through-hole contact portions, which are configured to electrically connect the second epitaxial layer of the first light-emitting mesa to the first electrode; and
the non-light-emitting area does not have through-hole contact portions for electrically connecting the second epitaxial layer of the dummy light-emitting mesa to the drive circuit.

In one embodiment, the light-emitting area further includes a top transparent conductive layer, which is arranged on the upper surface of the light-emitting mesa to electrically connect the first epitaxial layer to the second electrode; and
the non-light-emitting area does not have the top transparent conductive layer.

In one embodiment, the micro-LED chip further includes:
an insulating layer covering the light-emitting area and the non-light-emitting area.

In one embodiment, the first spacing between adjacent first light-emitting mesas in the light-emitting area is equal to the second spacing between adjacent dummy light-emitting mesas in the non-light-emitting area.

In one embodiment, the first spacing between adjacent first light-emitting mesas in the light-emitting area is different from the second spacing between adjacent dummy light-emitting mesas in the non-light-emitting area.

In one embodiment, the micro-LED chip further includes:
a passivation layer covering the lower surface of the first light-emitting mesa and the lower surface of the dummy light-emitting mesa, where the passivation layer on the first light-emitting mesa has notches to expose the bottom transparent conductive layer, and the passivation layer on the dummy light-emitting mesa does not have a notch.

In one embodiment, the micro-LED chip further includes:
a reflective mirror layer arranged to surround the first light-emitting mesa and configured to reflect light emitted from the first light-emitting mesa toward the light extraction side;
at least one drive circuit having a metal layer, a plurality of through-hole contact portions are arranged on the at least one drive circuit, and where the plurality of through-hole contact portions are electrically connected with the metal layer, and an area of the micro-LED array is bonded onto the drive circuit through a bottom conductive bonding layer, where the at least one drive circuit further comprises a wiring stacked layer below the metal layer, the wiring stacked layer is configured to lead out a first electrode;
an insulating layer configured to accommodate the first light-emitting mesa, the dummy light-emitting mesa, and the plurality of through-hole contact portions;
a first electrode electrically connected with the plurality of through-hole contact portions;
a top transparent conductive layer arranged on the surface of the passivation layer and in electrical contact with the second epitaxial layer; and
a second electrode arranged on the surface of the top transparent conductive layer.

In one embodiment, the polarity of the second electrode is opposite to the polarity of the first electrode.

In one embodiment, the material of the second epitaxial layer is a material layer of a second conductivity type including two or more elements of Ga, N, As, Al, In, and P, and the first epitaxial layer is a material layer of a first conductivity type including two or more elements of Ga, N, As, Al, In, and P, where the first conductivity type is different from the second conductivity type.

In one embodiment, the light-emitting layer includes a multi-quantum-well layer, where the multi-quantum-well layer is an InGaN/GaN multi-quantum-well layer, an InGaN/AlGaN multi-quantum-well layer, an InGaAs/AlGaAs multi-quantum-well layer, or an AlGaInP multi-quantum-well layer.

In one embodiment, a first side of the light-emitting layer is provided with an electron blocking layer, and the first side refers to a side along which electrons migrate out of the light-emitting layer.

In one embodiment, the material of the passivation layer is a Si₃N₄ film, a SiO₂ film, or an Al₂O₃ film.

In one embodiment, the material of the insulating layer is selected from one or more of the following items: silicon dioxide (SiO₂), aluminum oxide (Al₂O₃), silicon nitride (Si₃N₄), silicon carbide nitride (SiCN), hafnium oxide (HfO₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof; and/or
the material of the metal layer is selected from one or more of the following items: aluminum (Al), copper (Cu), tungsten (W), silver (Ag), gold (Au), nickel (Ni), platinum (Pt), tantalum (Ta), and molybdenum (Mo).

In another embodiment of the present invention, the through-hole contact portions include a first and a second through-hole contact portions, and the insulating layers include a first and a second insulating layers, and the micro-LED chip includes an upper stacked layer and a lower stacked layer, where the upper stacked layer includes the first insulating layer, the light-emitting mesa, and the first through-hole contact portion, and the lower stacked layer includes the second insulating layer, the second through-hole contact portion, and the drive circuit, where the lower stacked layer is jointed with the upper stacked layer through hybrid bonding, such that the first through-hole contact portion is bonded with the second through-hole contact portion, and the first insulating layer is bonded with the second insulating layer.

The present invention has at least the following beneficial effects:
(1) Through research, the applicant discovered that the primary cause of delamination when coating an insulating layer such as silicon dioxide on the light-emitting mesa is the presence of a concave-convex structure on the light-emitting mesa in the light-emitting area, while the non-light-emitting area is a planar structure, consequently, stresses generated by the insulating layer coated in the non-light-emitting area are easily transmitted to the light-emitting area, which increases shear stresses in the light-emitting area and causes delamination, wrinkling, or void formation of the insulating layer in the light-emitting area. Through research, the inventors further discovered that if the light-emitting mesa is etched in the light-emitting area, meanwhile, the same dummy light-emitting mesa is etched in the non-light-emitting area, on the one hand, the process is easy to achieve and the additional cost is low, because in order to etch the dummy light-emitting mesa, it is only required to expand the etching range of the epitaxial wafer; on the other hand, the concave-convex structure of the dummy light-emitting mesa in the non-light-emitting area can effectively suppress the stress transmission from the non-light-emitting area into the light-emitting area, thereby reducing the risks of delamination, wrinkling, and void formation of the insulating layer in the light-emitting area when coating the insulating layer; meanwhile, according to the stress formula: σ=F/A (σ is stress per unit area, F is the applied external force, and A is the force-bearing area), it can be seen that, by arranging the dummy light-emitting mesa in the non-light-emitting area, the surface area of the coated insulating layer is increased by the concave-convex structure, so that stress per unit area is reduced, consequently, the risks of delamination, wrinkling, and void formation in the non-light-emitting area are also reduced.
(2) Furthermore, through research, the inventor discovers that when the proportion of the area occupied by the dummy light-emitting mesa to the total chip area reaches is slightly less than 50%, i.e., 40% to 50%, preferably 44% (at this time, the light-emitting area accounts for 56%), the best effects of prevention of delamination, wrinkling, and void formation can be achieved.

### BRIEF DESCRIPTION OF THE DRAWINGS

The present invention is further explained below with reference to the accompanying drawings in conjunction with specific implementation methods.

FIG. 1 illustrates a schematic diagram of a first embodiment of an epitaxial wafer with a dummy light-emitting mesa according to the present invention;

FIG. 2 illustrates a schematic diagram of a light-emitting mesa according to the present invention;

FIG. 3 illustrates a schematic diagram of a second embodiment of an epitaxial wafer with a dummy light-emitting mesa according to the present invention;

FIG. 4 illustrates a schematic diagram of a third embodiment of an epitaxial wafer with a dummy light-emitting mesa according to the present invention;

FIG. 5 illustrates a schematic diagram of a micro-LED according to the present invention;

FIG. 6 illustrates a schematic diagram of a reflective mirror layer according to the present invention; and

FIG. 7 illustrates a top view schematic diagram of an epitaxial wafer according to the present invention.

### DESCRIPTION OF THE EMBODIMENTS

It should be noted that various components in the accompanying drawings may be exaggerated for the purpose of illustrative illustration and are not necessarily true to scale. In the accompanying drawings, components that are identical or functionally identical are provided with the same accompanying drawing reference signs.

In the present invention, unless otherwise specified, the words “arranged on”, “arranged above” and “arranged over” do not exclude the existence of intermediates between the two. Furthermore, “arranged on or above” merely indicates the relative positional relationship between the two components, but under certain circumstances, such as when the product direction is reversed, it can be converted to “arranged under or below”, and vice versa.

In the present invention, the embodiments are merely intended to illustrate the scheme of the present invention and should not be construed as limiting.

In the present invention, the quantifiers “a” and “one” do not exclude scenarios with a plurality of elements, unless otherwise specified.

In the present invention, the term “connect” may refer to either the two being directly connected or the two being indirectly connected through an intermediate component

In the present invention, the term “configure” refers to the arranging of the shape, structure, material, and/or function of a target object to achieve a desired technical effect, where “configure” includes various alternative technical means to achieve this technical effect, these technical means become apparent under the teachings of the present invention.

It should also be noted herein that in embodiments of the present invention, merely a part of the components or assemblies may be shown for the sake of clarity and simplicity, but those ordinary skilled in the art will be able to understand that the required components or assemblies may be added as needed according to specific scenarios in light of the teachings of the present invention. Furthermore, features in different embodiments of the present invention may be combined with each other unless otherwise indicated. For example, a feature in the second embodiment may be substituted for a corresponding or functionally identical or similar feature in the first embodiment, and the obtained embodiment also falls within the scope of the disclosure or the scope of the record of the present application.

It should also be noted that, within the scope of the present invention, the terms “the same”, “equal”, “equal to”, etc. do not mean that the two numerical values are absolutely equal, but rather allow for a certain reasonable error, that is to say, the terms also cover “substantially the same”, “substantially equal” and “substantially equal to”. By analogy, in the present invention, the terms “perpendicular to”, “parallel to”, etc., which indicate direction, also cover the meaning of “substantially perpendicular to”, “substantially parallel to”.

In the present invention, the term “configure” refers to the arranging of the shape, structure, material, and/or function of a target object to achieve a desired technical effect, where “configure” includes various alternative technical means to achieve this technical effect, these technical means become apparent under the teachings of the present invention.

In the present invention, the term “spacing between adjacent light-emitting mesas” refers to the edge distance between adjacent light-emitting mesas in a central longitudinal cross-section perpendicular to the bottom surface of the light-emitting mesa.

In the present invention, the term “light extraction side of the light-emitting mesa refers to the side from which light is emitted by the light-emitting mesa, i.e., the side from which light generated by the light-emitting mesa leaves the light-emitting mesa to output outward. For example, the light extraction side of the light-emitting mesa is the side where the microlens is located. Similarly, the term “a side of the light-emitting mesa facing away from the light extraction side” refers to the side of the light-emitting mesa opposite to the light extraction side, such as the side facing the drive circuit or the drive backplane.

In the present invention, the term “upward reflect” refers to light being reflected such that the distance between the reflected light and the upper surface of the light-emitting mesa increases. The upward direction includes directly above and diagonally above.

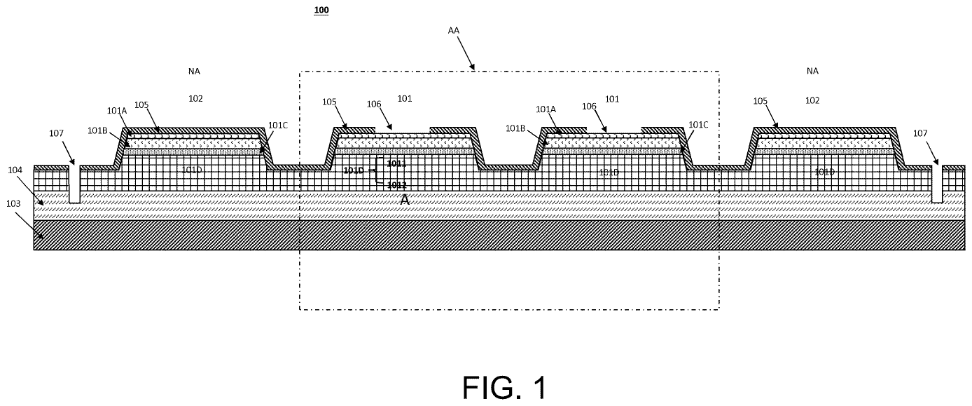

FIG. 1 illustrates a schematic diagram of a first embodiment of an epitaxial wafer 100 with a dummy light-emitting mesa according to the present invention.

As shown in FIG. 1, the epitaxial wafer 100 includes a light-emitting area AA and a non-light-emitting area NA. The non-light-emitting area NA is adjacent to the light-emitting area AA. A first light-emitting mesa 101 for light-emitting is arranged in the light-emitting area AA, while a non-luminous dummy light-emitting mesa 102 is arranged in the non-light-emitting area NA. The light-emitting area AA, for example, occupies 50% to 60% of the area of the epitaxial wafer 100, preferably 56%, while the non-light-emitting area NA, for example, occupies 40% to 50% of the area of the epitaxial wafer 100, preferably 44%. In the present invention, the epitaxial wafer refers to a substrate bearing an epitaxial layer, and the epitaxial layer may be unetched or etched (in the present invention, the epitaxial layer of the epitaxial wafer has been etched to form a part of the light-emitting mesa), and the epitaxial layer serves to provide the fundamental structure of the light-emitting mesa to perform subsequent processes (such as photolithography, etching, deposition, electroplating, and grinding, etc.) on its basis to form the micro-LED chip.

Furthermore, the epitaxial wafer 100 also includes a temporary substrate 103, a buffer layer 104, and dicing lanes 107. These components are explained below, respectively.

### Temporary Substrate

The epitaxial wafer 100 with a dummy light-emitting mesa according to the present invention may have a temporary substrate 103, which is configured to grow epitaxial layer and support the first light-emitting mesa 101 and the dummy light-emitting mesa 102 formed by etching the epitaxial layer. The thickness of the temporary substrate 103 may be, for example, 600 to 1000 μm, preferably 800 μm. For example, the temporary substrate 103 is used for the epitaxial growth of the epitaxial layers, i.e., the first epitaxial layer 101B, the light-emitting layer 101C, and the second epitaxial layer 101D, and for supporting the epitaxial layer and the bottom transparent conductive layer 101AA formed thereon during subsequent processes. Herein, the bottom transparent conductive layer 101AA is referred to as the “bottom transparent conductive layer” because it is arranged on the side of the light-emitting mesa facing away from the light extraction side A, i.e., it will be at the bottom of the finished chip. After the relevant processes are completed, the temporary substrate 103 can be removed, for example, the temporary substrate 103 is removed by debonding and grinding, such as CMP. The material of the temporary substrate 103 may include, for example: silicon (Si), silicon dioxide (SiO₂), silicon nitride (Si₃N₄), silicon carbide (SiC), gallium nitride (GaN), glass, aluminum nitride (AlN), sapphire (α-Al₂O₃), and germanium (Ge), etc.

### Buffer Layer

The epitaxial wafer 100 with a dummy light-emitting mesa according to the present invention may have a buffer layer 104 arranged between the second epitaxial layer 101D and the temporary substrate 103. The buffer layer 104 serves to mark the position of the second epitaxial layer 101D when temporary substrate 103 is removed to prevent damage to the second epitaxial layer 101D. For example, the buffer layer 104 may serve as an etch buffer layer or a grind buffer layer, its thickness is, for example, 5000 Å. After the relevant processes are completed, the buffer layer 104 can be removed, for example, the buffer layer 104 is removed by debonding and grinding, such as CMP. Materials of the buffer layer 104 may include for example, gallium nitride, silicon nitride, and silicon dioxide, etc.

### First Light-Emitting Mesa

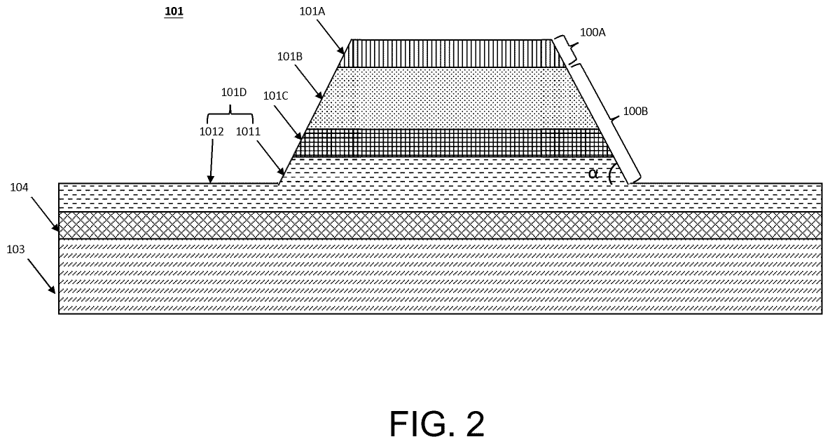

The epitaxial wafer 100 with a dummy light-emitting mesa according to the present invention has a first light-emitting mesa 101 located in the light-emitting area AA and arranged on the temporary substrate 103 or the buffer layer 104. The first light-emitting mesa 101 is arranged in the light-emitting area AA and configured to emit light. As shown in FIG. 1, the side surface inclination angle α (see FIG. 2) of the light-emitting mesa 101 may, for example, be 55° to 75°, particularly 60° to 70°, thereby a good aperture ratio for the micro-LED chip is achieved. The first light-emitting mesa 101 sequentially has, starting from the side facing away from the light extraction side A: a bottom transparent conductive layer 101AA, a first epitaxial layer 101B, a light-emitting layer 101C, and a second epitaxial layer 101D. The diameter of the lower surface of the light-emitting mesa 101 may be, for example, 0.8 to 1.2 μm, preferably 1.0 μm. The diameter of the upper surface of the light-emitting mesa 101 may be, for example, 1.4 to 1.8 μm, preferably 1.6 μm. The height of the light-emitting mesa may be, for example, 0.3 to 0.7 μm, preferably 0.5 μm. Furthermore, the first light-emitting mesa 101 also has a passivation layer 105 on its lower surface facing away from the light extraction side A and the side surface. These layers are described below, respectively.

The bottom transparent conductive layer 101A is arranged on the side of the first light-emitting mesa 101 facing away from the light extraction side A, i.e., the side facing the drive circuit. The function of the bottom transparent conductive layer 101A is to electrically connect the first epitaxial layer 101B in the first light-emitting mesa 101 to the drive circuit, particularly the first electrode, such as the anode. The material of the bottom transparent conductive layer 101A may be, for example, a metal oxide such as indium tin oxide ITO or zinc oxide ZnO, etc., and its formation methods may include, for example, physical vapor deposition (PVD), chemical vapor deposition (CVD), sol-gel method, solution coating method, etc. The thickness of the bottom transparent conductive layer 101A may be, for example, 1350 Å, and its width may be, for example, 1.0 μm. The bottom transparent conductive layer 101A and other layers of the first light-emitting mesa 101 may be etched in the same etching step or be etched in different etching steps. The thickness of the bottom transparent conductive layer 101A may be, for example, 800 to 1500 μm.

Referring to FIG. 2, the formation process of the first light-emitting mesa 101 is explained below using different etching step methods as an example. Firstly, the bottom transparent conductive layer 101A is formed on the first epitaxial layer 101B, then, in a first etching step, the bottom transparent conductive layer 101A is etched to form a first inclined edge 100A of the bottom transparent conductive layer 101A. Then, in a second etching step, the first epitaxial layer 101B, the light-emitting layer 101C, and the second epitaxial layer 101D are etched to form the second inclined edge 100B of the entire first light-emitting mesa 101. The inclination angle of the first inclined edge 100A may be equal to the inclination angle of the second inclined edge, for example, they both are within the range of 55° to 75°, particularly 60° to 70°. Alternatively, the inclination angle of the first inclined edge may be larger, for example greater than 70°, particularly greater than 75°, while the inclination angle of the second inclined edge may be less than 75°, particularly less than 70°; since the thickness of the bottom transparent conductive layer 101A is significantly less than the sum of the thicknesses of the first epitaxial layer 101B, the light-emitting layer 101C, and the second epitaxial layer 101D, the average of the inclination angle of the first inclined edge 100A and the second inclined edge 100B on the total height of the light-emitting mesa can still fall within the range of 55° to 75°, particularly 60° to 70°. For example, the first inclined edge 100A of the bottom transparent conductive layer 101A has a first inclination angle X, and the thickness of the bottom transparent conductive layer 101A is d1, while the second inclined edge 100B of the first epitaxial layer 101B, the light-emitting layer 101C, and the second epitaxial layer 101D has a second inclination angle Y, and the first epitaxial layer 101B, the light-emitting layer 101C, and the second epitaxial layer 101D have a thickness d2. The average inclination angle d of the light-emitting mesa 100 over the entire thickness is:

$$d = ( X * d 1 + Y * d 2 ) / ( d 1 + d 2 ) .$$

Herein, d falls within the range of 55° to 75°, particularly 60° to 70°. That is to say, even if the layers etched during different etching steps have different inclination angles, a good aperture ratio can still be ensured as long as the average inclination angle d is within the aforementioned range. For example, with X=85°, and Y=65°, since d1=d2/10, the average inclination angle d=66.8°.

In another case, the first inclined edge 100A and the second inclined edge 100B are not equal to each other, but their inclination angles are both within the range of 55° to 75°, particularly 60° to 70°. Herein, “the inclination angle of the inclined edge” refers to the angle formed by the inclined edge and the bottom surface of the first light-emitting mesa 101 when seen from the cross-sectional view of the first light-emitting mesa 101, and the direction of the bottom surface of the first light-emitting mesa 101 may be characterized, for example, by the length extension direction of the second epitaxial layer 101D. Furthermore, in the present embodiment, the end of the first inclined edge 100A and the end of the second inclined edge 100B are connected with each other, i.e., in a smooth transition. In other embodiments, the end of the first inclined edge 100A and the end of the second inclined edge 100B may also be in non-smooth transition, i.e., their adjacent ends in the horizontal direction have a certain distance between them, and the distance is less than or equal to 0.2 μm. In case of the light-emitting mesa with an inclination angle between 55° and 75°, particularly between 60° and 70°, on the one hand, a good aperture ratio is ensured, on the other hand, a good area ratio between the first and second epitaxial layers and the light-emitting layer is also achieved.

The first epitaxial layer 101B is arranged between the bottom transparent conductive layer 101A and the light-emitting layer 101C. The light-emitting layer 101C is arranged between the first epitaxial layer 101B and the second epitaxial layer 101D and is configured to emit light. The second epitaxial layer 101D is arranged on the side of the first light-emitting mesa 101 facing the light extraction side A, where the area of the second epitaxial layer 101D is greater than the area of the first epitaxial layer 101B, and the side surface of the first light-emitting mesa 101 has an inclined surface, the inclination angle α of the inclined surface is of 55° to 75°, preferably 60° to 70°. The thickness of the first epitaxial layer 101B may be, for example, 2500 to 3500 angstroms; the thickness of the light-emitting layer 101C may be, for example, 2000 to 4000 angstroms; and the thickness of the second epitaxial layer 101D may be, for example, 4000 to 5000 angstroms. The exemplary formation process for the first epitaxial layer 101B, the light-emitting layer 101C, and the second epitaxial layer 101D may be referenced to the description of the formation process for the bottom transparent conductive layer 101A in FIG. 2.

Furthermore, the second epitaxial layer 101D of the light-emitting mesa 101 includes two portions, i.e., a step portion 1011 and a base portion 1012. The step portion 1011 is in electrical contact with the light-emitting layer 101C, and the base portion 1012 extends from the step portion 1011 to two sides, i.e., extend beyond the step portion 1011. In one embodiment, the thickness of the step portion 1011 is 2000 Å, and the thickness of the base portion 1012 is 1000 Å. Herein, the second inclined edge 100B includes the inclined surfaces of the first epitaxial layer 101B, the light-emitting layer 101C, and the step portion 1011. The base portion 1012 may extend to adjacent light-emitting mesas and be continuously connected with its base portion. In the present embodiment, not only the thickness of the second epitaxial layer 101D can be increased, but also its surface area facing the light-emitting side A is not limited by the slope, but can extend to adjacent light-emitting mesas, so that the luminous efficiency is improved.

In some embodiments, the light-emitting layer is formed by a plurality of stacked quantum well layers, particularly superlattice-stacked quantum well layers. Preferably, the superlattice-stacked quantum well layers include a plurality of pairs of quantum well layers stacked with quantum barrier layers. In some embodiments, the first epitaxial layer is a semiconductor material with a first conductivity type and includes a plurality of semiconductor layers. Its main matrix material may be, but is not limited to, composed of materials such as Ga, N, As, P, In, or Al, etc. Furthermore, the first epitaxial layer may include, from top to bottom, but is not limited to, a waveguide layer, a confinement layer, a transition layer, and a window layer; furthermore, an ohmic contact layer may be formed below the window layer. In some embodiments, the second epitaxial layer is a semiconductor material with a second conductivity type and includes a plurality of semiconductor layers. The main matrix material of the second epitaxial layer may include, but is not limited to, materials such as Ga, N, As, P, In, or Al, etc. Furthermore, the second epitaxial layer may include, from top to bottom, but is not limited to, a confinement layer and a waveguide layer; furthermore, in some embodiments, an ohmic contact layer may be formed on the confinement layer. In one embodiment, the first conductivity type is different from the second conductivity type.

In one embodiment, the second epitaxial layer is an N-type GaN layer or an N-type AlGaN layer, and the first epitaxial layer is a P-type GaN layer or a P-type AlGaN layer, i.e., the material of the second epitaxial layer is a material layer of a second conductivity type including two or more elements of Ga, N, As, Al, In, and P, and the first epitaxial layer is a material layer of a first conductivity type including two or more elements of Ga, N, As, Al, In, and P. In one embodiment, the light-emitting layer includes a multi-quantum-well layer and an electron barrier layer, and the multi-quantum-well layer is an InGaN/GaN multi-quantum-well layer, or an InGaN/AlGaN multi-quantum-well layer, or an InGaAs/AlGaAs multi-quantum-well layer. In another embodiment, the second epitaxial layer may also be a P-type GaN layer or a P-type AlGaN layer, and the first epitaxial layer is an N-type GaN layer or an N-type AlGaN layer.

In some embodiments, the light-emitting layer includes at least one quantum well layer. The thickness of the quantum well layer is between 20 nm and 40 nm, for example, the thickness is 30 nm. In some embodiments, the material of the quantum well layer is GaInP/(AlxGa1−x)yIn1−yP, where the range of x is 0.5 to 0.9, and the range of y is 0.3 to 0.5. For example, x is 0.8 and y is 0.5. In some embodiments, the relationship between x and y is that x is 1 to 2 times y. In some embodiments, the light-emitting layer is a multi-quantum well (MQW).

In embodiments of the present invention, one of the first epitaxial layer and the second epitaxial layer is an N-type semiconductor layer, and the other is a P-type semiconductor layer. In some embodiments, the N-type semiconductor layer also includes a doped N-type contact layer and an N-type cladding layer. The material of the N-type cladding layer is AlxIn1−xP, where the range of x is 0.1 to 0.5, for example, x is 0.5. Furthermore, in these embodiments, the thickness of the N-type cladding layer is no greater than 350 nm, for example, the thickness of the N-type cladding layer is 320 nm. The doping concentration of the N-type cladding layer is 5e¹⁷ cm⁻³ to 1e¹⁸ cm⁻³. In some embodiments, the N-type semiconductor layer also includes a doped N-type contact layer and an N-type cladding layer formed on the doped N-type contact layer. The doped N-type contact layer is configured to bond with the bonding layer. The material of the doped N-type contact layer is GaAs. In some embodiments, the thickness of the doped N-type contact layer is 10 nm to 30 nm. In some embodiments, the doping concentration of the doped N-type contact layer is 2e¹⁸ cm⁻³ to 1e¹⁹ cm⁻³. In some embodiments, the N-type semiconductor layer also includes an N-type spacer layer formed on the N-type cladding layer. The material of the N-type spacer layer is (AlxGa1−x)yIn1−yP, where the range of x is 0.5 to 0.9, and the rgaen of y is 0.1 to 0.5. For example, x is 0.8 and y is 0.5. In some embodiments, the relationship between x and y is that x is 1 to 2 times y. The thickness of the N-type spacer layer is 50 nm to 75 nm, for example 65 nm. In some embodiments, the P-type semiconductor layer includes a P-type cladding layer and a doped P-type contact layer. The P-type cladding layer is formed on the light-emitting layer, and the doped P-type contact layer is formed on the P-type cladding layer.

In some embodiments, the material of the P-type cladding layer is AlxIn1−xP, where x is 0.3 to 0.5, for example, x is 0.5. In such embodiments, the thickness of the P-type cladding layer is no greater than 380 nm, for example, the thickness of the P-type cladding layer is 360 nm.

In some embodiments, the material of the doped P-type contact layer is GaAs. The thickness of the doped P-type contact layer is 10 nm to 30 nm, for example 20 nm.

In some embodiments, the P-type semiconductor layer also includes a P-type spacer layer formed below the P-type cladding layer, a first doped P-type transition layer formed on the P-type cladding layer, and a second doped P-type transition layer formed on the first doped P-type transition layer. In some embodiments, the material of the P-type spacer layer is (AlxGa1−x)yIn1−yP, where the range of x is 0.5 to 0.9, and the range of y is 0.3 to 0.5. For example, x is 0.8 and y is 0.5. In some embodiments, the relationship between x and y is that x is 1 to 2 times y. The thickness of the P-type spacer layer is 50 nm to 75 nm, for example 65 nm.

In some embodiments, the material of the first doped P-type transition layer is (AlxGa1−x)yIn1−yP, where the range of x is 0.1 to 0.3, and the range of y is 0.3 to 0.5. For example, x is 0.17 and y is 0.5. In some embodiments, the relationship between x and y is that y is 1 to 5 times x. In some implementations, the thickness of the first doped P-type transition layer is 20 nm to 40 nm, for example 30 nm.

In some embodiments, the material of the second doped P-type transition layer is AlxGa1−xAs, where the range of x is 0.5 to 0.9, for example x is 0.6. In some embodiments, the thickness of the second doped P-type transition layer is 10 nm to 30 nm, for example 20 nm.

In some embodiments, the doping concentration of the second doped P-type transition layer is greater than the doping concentration of the first doped P-type transition layer. The doping concentration of the doped P-type contact layer is 1 to 10 times the doping concentration of the second doped P-type transition layer.

In some embodiments, the doping concentration of the doped P-type contact layer is greater than the doping concentration of the second doped P-type transition layer. Furthermore, in some embodiments, the doping concentration of the second doped P-type transition layer is 2 to 4 times the doping concentration of the first doped P-type transition layer.

For example, the doping concentration of the first doped P-type transition layer i greater than 1e¹⁸ cm³, the doping concentration of the second doped P-type transition layer is in the range of 2e¹⁸ cm⁻³ to 4e¹⁸ cm⁻³, and the doping concentration of the doped P-type contact layer is greater than 5e¹⁸ cm⁻³.

The passivation layer 105 extends on the surface of the light-emitting mesa 101 facing away from the light extraction side A and on the side surface. The function of the passivation layer 105 is not only to reduce current leakage at the sidewall, but also to passivate sidewall defects and block damage to the light-emitting mesa caused by water, oxygen, etc., during operation, it can also prevent metal in the reflector layer, cathode, etc. in the micro-LED diffuse to the light-emitting mesa 101 or insulation layer where it is located. The passivation layer 105 may be formed by depositing SiO₂ material using a CVD process, or by depositing Al₂O₃ material using an ALD process.

The passivation layer 105 has notches 106 on the first light-emitting mesa 101, and the notches 106 pass through the passivation layer 105 to expose the bottom transparent conductive layer 101A of the first light-emitting mesa 101. The functions of the notches 106 are to enable subsequent conductive structures, such as through-hole contact portions, to be electrically connected with the top transparent conductive layer 101A for connection to electrodes or drive circuits, thereby enabling the first light-emitting mesa 101 to emit light. On the contrary, the passivation layer 105 on the dummy light-emitting mesa 102 does not have the notches 106, consequently, the top transparent conductive layer 101A of the dummy light-emitting mesa 102 cannot be electrically connected with electrodes or drive circuits, such that the dummy light-emitting mesa 102 does not emit light in the finished micro-LED. The formation method of the passivation layer 105 may be, for example, as follows: firstly, a material layer of the passivation layer (e.g., silicon dioxide or aluminum oxide) is deposited on the light-emitting mesa, where the material layer can completely cover the first light-emitting mesa 101, the dummy light-emitting mesa 102, and the area between them; then, photolithography or etching is performed on the passivation layer of the first light-emitting mesa 101 in the light-emitting area AA to form the notches 106, and the notches 106 can expose at least a part of the bottom transparent conductive layer 1101 of the first light-emitting mesa 101. The size of the notches is, for example, 30% to 90% of the width of the top transparent conductive layer 101A.

### Dummy Light-Emitting Mesa

The epitaxial wafer 100 according to the present invention also includes a dummy light-emitting mesa 102, which is located in the non-light-emitting area NA and arranged on the temporary substrate 103 or the buffer layer 104. The dummy light-emitting mesa 102 is arranged in the non-light-emitting area NA and does not emit light. From FIG. 1, it can be seen that the side surface inclination angle α (see FIG. 2) of the dummy light-emitting mesa 102 may also be of, for example, 55° to 75°, particularly 60° to 70°. The dummy light-emitting mesa 102 sequentially has, starting from the side facing away from the light extraction side A, a bottom transparent conductive layer 101AA, a first epitaxial layer 101B, a light-emitting layer 101C, and a second epitaxial layer 101D. Furthermore, the dummy light-emitting mesa 102 also has a passivation layer 105 arranged on its lower surface facing away from the light extraction side A and on its side surface.

The bottom transparent conductive layer 101AA, the first epitaxial layer 101B, the light-emitting layer 101C, and the second epitaxial layer 101D of the dummy light-emitting mesa 102 are the same as those of the first light-emitting mesa 101, the difference lies in that, the passivation layer 105 on the dummy light-emitting mesa 102 does not have a notch 106, such that the top transparent conductive layer 101A of the dummy light-emitting mesa 102 is not exposed, and in the micro-LED finished in the subsequent process, the dummy light-emitting mesa 102 does not emit light. It should be noted that although in the present embodiment, the bottom transparent conductive layer 101AA, the first epitaxial layer 101B, the light-emitting layer 101C, and the second epitaxial layer 101D of the dummy light-emitting mesa 102 are the same as those of the first light-emitting mesa 101, they may be different in other embodiments, for example, the depth of the dummy light-emitting mesa 102 may be different from the depth of the first light-emitting mesa 101, or the diameter of the upper surface of the dummy light-emitting mesa 102 may be different from the diameter of the upper surface of the first light-emitting mesa 101, or the diameter of the lower surface of the dummy light-emitting mesa 102 may be different from the diameter of the lower surface of the first light-emitting mesa 101, or again the spacing between the dummy light-emitting mesas 102 may be different from the spacing between the first light-emitting mesas 101.

The principles on which the present invention is based are explained below.

Through research, the applicant discovered that the primary cause of delamination when coating an insulating layer such as silicon dioxide on the first light-emitting mesa 101 is the presence of a concave-convex structure on the first light-emitting mesa 101 in the light-emitting area AA, while the non-light-emitting area NA is a planar structure, consequently, stresses generated by the insulating layer coated in the non-light-emitting area NA are easily transmitted to the light-emitting area AA, which increases shear stresses in the light-emitting area AA and causing delamination, wrinkling, or void formation of the insulating layer in the light-emitting area AA. Through research, the inventors further discovered that if the light-emitting mesa is etched in the light-emitting area AA, meanwhile, the same dummy light-emitting mesa 102 is etched in the non-light-emitting area NA, then on the one hand, the process is easy to achieve and the additional cost is low, because in order to etch the dummy light-emitting mesa 102, it is only required to expand the etching range of the epitaxial wafer 100; on the other hand, the concave-convex structure of the dummy light-emitting mesa 102 in the non-light-emitting area can effectively suppress the stress transmission from the non-light-emitting area into the light-emitting area, thereby reducing the risks of delamination, wrinkling, and void formation of the insulating layer in the light-emitting area when coating the insulating layer; meanwhile, according to the stress formula: σ=F/A (σ is stress per unit area, F is the applied external force, and A is the force-bearing area), it can be seen that, by arranging the dummy light-emitting mesa 102 in the non-light-emitting area NA, the surface area of the coated insulating layer is increased by its concave-convex structure, so that stress per unit area is reduced, consequently, the risks of delamination, wrinkling, and void formation in the non-light-emitting area NA are also reduced. Furthermore, through research, the inventor discovered that when the proportion of the area occupied by the dummy light-emitting mesa 102 to the total chip area reaches slightly less than 50%, i.e., 40% to 50%, preferably 44% (at this time, the light-emitting area accounts for 56%), the best effects of prevention of delamination, wrinkling, and void formation can be achieved.

### Dicing Lanes

The epitaxial wafer 100 according to the present invention optionally has dicing lanes 107 arranged in the non-light-emitting area NA, particularly arranged between adjacent dummy light-emitting mesas 102. The dicing lanes 107 serve to separate adjacent light-emitting diode chips. Preferably, the dicing lanes are formed after the entire structure of the micro-LEDs has been formed on the epitaxial wafer 100. The widths of the dicing lanes may be, for example, 60 to 100 μm, and the depth may be, for example, 100 to 300 μm. In order to separate the chips, cutting methods for the dicing lanes include, for example: grinding wheel cutting, laser cutting, invisible cutting, etc. In order to form the dicing lanes, methods include, for example: mechanical cutting, laser cutting, photolithography, etching, etc.

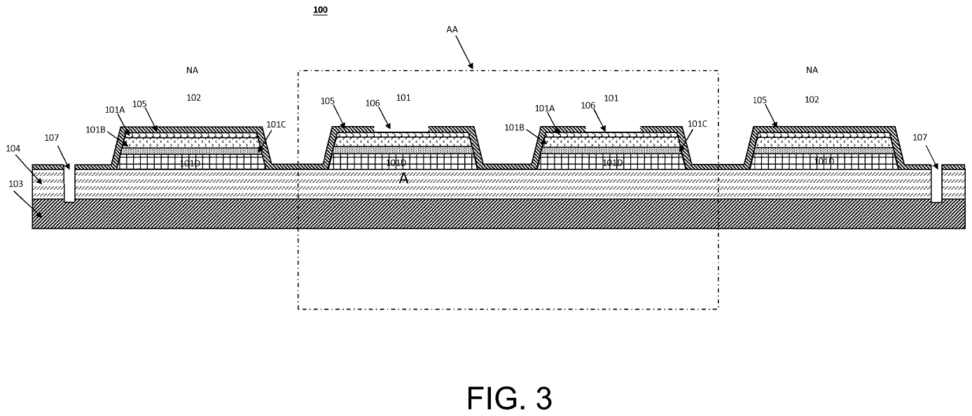

FIG. 3 illustrates a schematic diagram of a second embodiment of an epitaxial wafer 100 with a dummy light-emitting mesa according to the present invention.

The epitaxial wafer 100 in the second embodiment in FIG. 3 is substantially the same as the first embodiment in FIG. 1, the main difference lies in that, in the second embodiment, the second epitaxial layer 101D merely includes a step portion, but does not include a base portion, that is to say, the second epitaxial layer 101D is completely located within the upside-down arranged trapezoidal structure of the light-emitting mesa 101. In the present embodiment, the epitaxial layers 101D of the first light-emitting mesa 101 and the dummy light-emitting mesa 102 are the same, i.e., they neither include a base portion, that is to say, they are completely located within the upside-down arranged trapezoidal structure of the light-emitting mesa 101. Herein, the second epitaxial layers 101D of adjacent light-emitting mesas are disconnected from each other and are not connected together. Such light-emitting mesa structure allows for a thinner light-emitting mesa thickness.

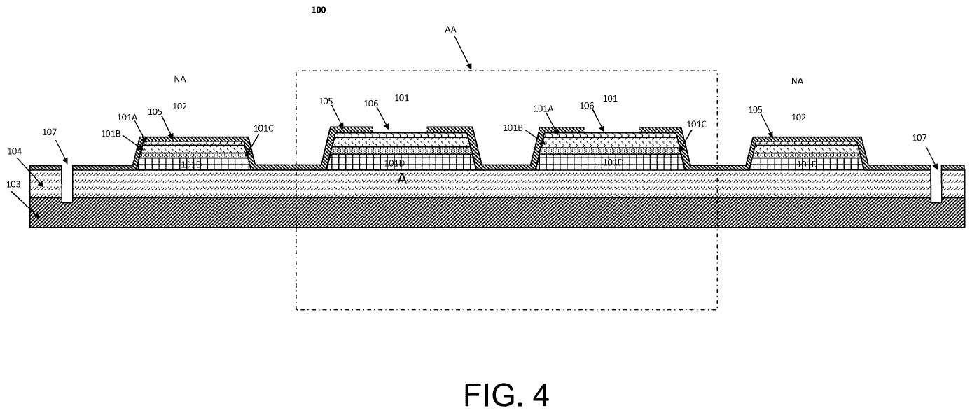

FIG. 4 illustrates a schematic diagram of a third embodiment of an epitaxial wafer with 100 a dummy light-emitting mesa according to the present invention.

The epitaxial wafer 100 in the third embodiment in FIG. 4 is substantially the same as that in the second embodiment in FIG. 3, the main difference lies in that, in the third embodiment, the depth of the dummy light-emitting mesa 102 is different from the depth of the first light-emitting mesa 101, the diameter of the upper surface of the dummy light-emitting mesa 102 is different from the diameter of the upper surface of the first light-emitting mesa 101, or the diameter of the lower surface of the dummy light-emitting mesa 102 is different from the diameter of the lower surface of the first light-emitting mesa 101, and the spacing between the dummy light-emitting mesas 102 is also different from the spacing between the first light-emitting mesas 101.

For example, the depth of the dummy light-emitting mesa 102 may be 50% to 150% of the depth of the first light-emitting mesa 101. In the present embodiment, the depth of the dummy light-emitting mesa 102 is less than the depth of the first light-emitting mesa 101, however, in other embodiments, the depth of the dummy light-emitting mesa 102 may also be greater than the depth of the first light-emitting mesa 101.

For example, the diameter of the upper surface of the dummy light-emitting mesa 102 may be 50% to 150% of the diameter of the upper surface of the first light-emitting mesa 101. In the present embodiment, the diameter of the upper surface of the dummy light-emitting mesa 102 is less than the diameter of the upper surface of the first light-emitting mesa 101, however, in other embodiments, the diameter of the upper surface of the dummy light-emitting mesa 102 may also be larger than the diameter of the upper surface of the first light-emitting mesa 101.

For example, the diameter of the lower surface of the dummy light-emitting mesa 102 may be 50% to 150% of the diameter of the lower surface of the first light-emitting mesa 101. In the present embodiment, the diameter of the lower surface of the dummy light-emitting mesa 102 is less than the diameter of the lower surface of the first light-emitting mesa 101, however, in other embodiments, the diameter of the lower surface of the dummy light-emitting mesa 102 may also be larger than the diameter of the lower surface of the first light-emitting mesa 101.

For example, the spacing between the dummy light-emitting mesas 102 may be 50% to 150% of the spacing between the first light-emitting mesas 101. In the present embodiment, the spacing between the dummy light-emitting mesas 102 is less than the spacing between the first light-emitting mesas 101, however, in other embodiments, the spacing between the dummy light-emitting mesas 102 may also be greater than the spacing between the first light-emitting mesas 101.

Compared with the first light-emitting mesa 101, the smaller depth, smaller lower surface diameter, smaller upper surface diameter, or greater spacing of the dummy light-emitting mesa 102 can reduce the process cost of forming the dummy light-emitting mesa 102, or reduce the area occupied by the dummy light-emitting mesa 102, or reduce the chip thickness at the dummy light-emitting mesa 102. While compared with the first light-emitting mesa 101, the greater depth, greater lower surface diameter, greater upper surface diameter, or smaller spacing of the dummy light-emitting mesa 102 can increase the area occupied by the dummy light-emitting mesa 102, thereby enhancing the stress removal effect. The appropriate dimensions and spacing of the dummy light-emitting mesa 101 can be selected according to the specific application requirements.

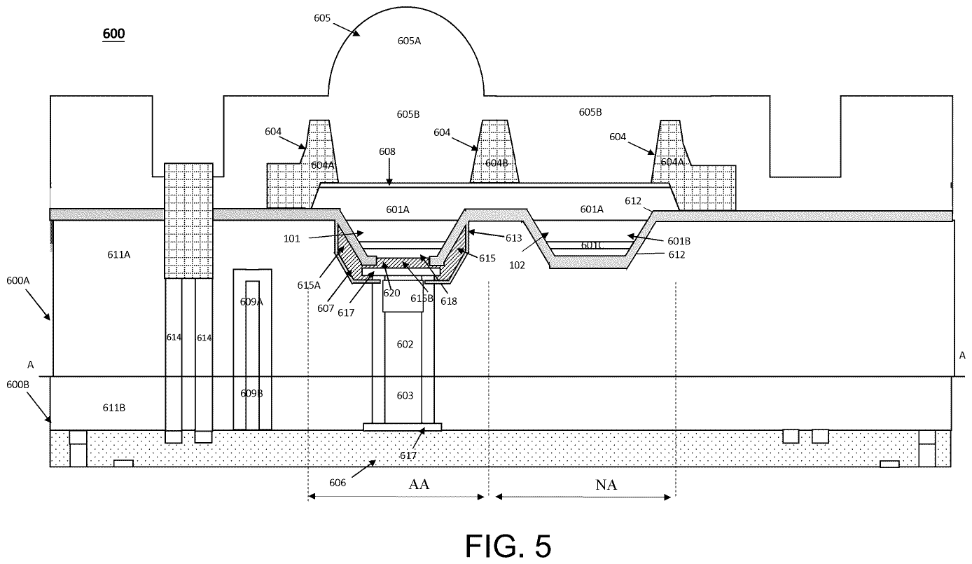

FIG. 5 illustrates a schematic diagram of the micro-LED chip 600 according to the present invention. In the present embodiment, the first light-emitting mesa or epitaxial layer of the micro-LED chip 600 has an upside-down arranged trapezoidal structure, i.e., its first light-emitting mesa is a structure with a larger upper surface and a smaller lower surface. The micro-LED chip 600 includes a light-emitting area AA and a non-light-emitting area NA, where the first light-emitting mesa 101 is arranged in the light-emitting area AA, and the dummy light-emitting mesa 602 is arranged in the non-light-emitting area NA. The first light-emitting mesa is configured to emit light, whereas the dummy light-emitting mesa 602 does not emit light.

The various components of the micro-LED chip 600 are described in detail below.

As shown in FIG. 5, the micro-LED chip 600 according to the present invention includes an upper stacked layer 600A and a lower stacked layer 600B, where the upper stacked layer 600A and the lower stacked layer 600B form a complete micro-LED chip 600 through hybrid bonding at the interface A. It should be noted that the structure of these upper and lower stacked layers is merely exemplary, in other embodiments, micro LED chips with other structures may also be used. The structure and components of the upper stacked layer 600A and lower stacked layer 600B are described in detail below.

### Upper Stacked Layer

The upper stacked layer 600A includes a first insulating layer 611A, a first light-emitting mesa 101, a dummy light-emitting mesa 102, a transparent conductive layer 608, a first electrode 604 (cathode), a first through-hole contact portion 602, a second electrode 610 (anode), a first bonding mark 609A, and microlens 605. The various components are described below, respectively.

The first insulating layer 611A is configured to accommodate at least a part of the first light-emitting mesa 101 and provide electrical insulation for it. Herein, the first insulating layer 611A has a recess 607 configured to accommodate the light-emitting layer and the second epitaxial layer as well as the ancillary structures of the first light-emitting mesa 101. For a detailed description of the first light-emitting mesa 101 and its ancillary structures (such as the passivation layer 612, the reflective mirror layer 615, etc.), reference may be made to the first light-emitting mesa 101 and description thereof. Herein, it should be noted that the recess 607 may be formed after the first light-emitting mesa 101, i.e. the first light-emitting mesa 101 and its ancillary structures are first formed on a temporary substrate, then on the light-emitting mesa and its ancillary structures, the first insulating layer 611A surrounding them is formed. The material of the first insulating layer 611A may be, for example, silicon dioxide, silicon nitride, high-k dielectric materials (such as hafnium oxide, aluminum oxide, etc.), and so on. Methods for forming the first insulating layer 611A may include thermal oxidation, chemical vapor deposition (CVD), etc. The thickness of the first insulating layer 611A is, for example, 1 to 3 μm, preferably 2 μm, and more preferably 0.6 to 1.4 μm. Furthermore, the first insulating layer 611A may be planarized at interface A (e.g., through chemical mechanical polishing CMP) to facilitate hybrid bonding with the second insulating layer 611B.

The first insulating layer 611A is transparent to light emitted from the first light-emitting mesa 101. In some embodiments, the first insulating layer 611A is made of a dielectric material such as solid inorganic material or plastic material. In some embodiments, the solid inorganic material includes silicon dioxide (SiO₂), aluminum oxide (Al₂O₃), silicon nitride (Si₃N₄), silicon carbide nitride (SiCN), hafnium oxide (HfO₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof. In some embodiments, the plastic material includes polymers such as SU-8, PermiNex, or benzocyclobutene (BCB), or transparent plastics (resins) including spin-on glass (SOG), or adhesive micro resist BCL-1200, or any combination thereof. In some embodiments, the first insulating layer 611A may facilitate the passage of light emitted from the first light-emitting mesa 101. In some embodiments, the first insulating layer 611A may include a plurality of portions, such as three embedded dielectric portions and two adhering dielectric portions. The embedded dielectric portions refer to the dielectric layers surrounding each light-emitting diode structure; while the adhering dielectric portions refer to the dielectric layers between two light-emitting diode structures. The embedded dielectric portions and the adhering dielectric portions may have the same or different compositions.

Herein, due to the presence of the dummy light-emitting mesa 102, the stress, particularly shear stress on the first insulating layer 611A is significantly reduced, such that the probability of delamination, wrinkling, or voids forming between the first insulating layer 611A and the light-emitting mesa is significantly reduced, and thus the chip quality of the micro-LED 600 is improved, and the risk of failure is reduced.

The first light-emitting mesa 101 is configured to emit light, where the top surface (i.e., upper surface) area of the first light-emitting mesa 101 is greater than the bottom surface (i.e., lower surface) area of the first light-emitting mesa 101, the first light-emitting mesa 101 is in the shape of an upside-down arranged trapezoid. The inclination angle of the first light-emitting mesa 101 may be, for example, 10° to 85°, preferably 30° to 70°, and particularly 35° to 50°. The first light-emitting mesa 101 includes a first epitaxial layer 601A, a light-emitting layer 601B, and a second epitaxial layer 601C, where the first epitaxial layer 601A is arranged on the top surface or the upper surface of the light-emitting mesa, i.e., the side facing the light extraction surface; the light-emitting layer 601B is arranged in the recess 607 and arranged between the first epitaxial layer 601A and the second epitaxial layer 601C; and the second epitaxial layer 601C is arranged on the bottom or lower surface of the first light-emitting mesa 101, i.e., the side facing the drive circuit 606. The light-emitting layer 601B may include, for example, a multi-quantum-well layer and an electron barrier layer. In one embodiment of the present invention, the first epitaxial layer 601A is an N-type GaN layer or an N-type AlGaN layer, and the second epitaxial layer 601C is a P-type GaN layer or a P-type AlGaN layer, i.e., the material of the second epitaxial layer is a material layer of a second conductivity type including two or more elements of Ga, N, As, Al, In, and P, and the first epitaxial layer is a material layer of a first conductivity type including two or more elements of Ga, N, As, Al, In, and P. The multi-quantum-well layer is an InGaN/GaN multi-quantum-well layer, an InGaN/AlGaN multi-quantum-well layer, or an InGaAs/AlGaAs multi-quantum-well layer. The electron barrier layer is arranged on the first side of the light-emitting layer, and the first side refers to the side along which electrons migrate out of the light-emitting layer. In yet another embodiment of the present invention, the first epitaxial layer may also be a P-type GaN layer or a P-type AlGaN layer, and the second epitaxial layer is an N-type GaN layer or an N-type AlGaN layer. The top width of the first light-emitting mesa 101 is, for example, 0.5 to 3 μm, preferably 1.0 to 2.0 μm. The thickness of the first epitaxial layer 601A is, for example, 4000 to 5000 angstroms, the thickness of the light-emitting layer 601B is, for example, 2000 to 4000 angstroms, and the thickness of the second epitaxial layer 601C is, for example, 2500 to 3500 angstroms. 1 angstrom=10\hat{ }(−10) m. From FIG. 5, it can also be seen that the first epitaxial layer 601A is located outside the recess 607, while the light-emitting layer 601B and the second epitaxial layer 601C are located within the recess 607, therefore, the surface area of the first epitaxial layer 601A is not limited by the aperture area of the recess 607 but can be significantly greater than the aperture area of the recess 607, thereby significantly increasing the area and thickness of the first epitaxial layer 601A; furthermore, due to the fact that merely the light-emitting layer 601B and the second epitaxial layer 601C need to be accommodated in the recess 607, these two layers have a larger area and thickness compared to the structure that requires accommodating three layers in the prior art, and thus the area and thickness of the epitaxial layer 601 are better increased, and the light output is improved. It can also be seen herein that the first epitaxial layer 601A passes through the first electrode 604 (herein is the cathode) from below the first electrode 604, so that the first epitaxial layers 601A of adjacent light-emitting mesas 601 can be connected to each other, and thus in the case of a common-cathode structure (i.e., where the first epitaxial layers of all micro-LEDs in the same array are connected to a common cathode), it can significantly enhance the conductivity between the cathode 604 and the first epitaxial layers 601A compared to the case where it is connected to the cathode 604 solely by the transparent conductive layer 608 covering it, the conductivity between the cathode 604 and the first epitaxial layer 601A can be significantly enhanced, thereby increasing its power supply. Furthermore, the contact cross-section between the first epitaxial layer 601A and the cathode 604 at the edge is partially planar and partially inclined surface. The inclined surface increases the contact area between the first epitaxial layer 601A and the cathode 604 compared to a vertical surface, and thus the conductivity is increased.

The first light-emitting mesa 101 also includes ancillary structures such as passivation layers 612 and 613, a reflective mirror layer 615, and a bottom transparent conductive layer 618, etc. The passivation layer 612 is arranged between the first light-emitting mesa 101 and the reflective mirror layer 615, and optionally extends on the upper surface of the first insulating layer 611A, and the passivation layer 613 is arranged between the inner wall of the recess 607 and the reflective mirror layer 615, and optionally extends on the upper surface of the first insulating layer 611A. In another embodiment, merely one of the passivation layers 612 and 613 extends on the upper surface of the first insulating layer 611A, or neither of them extends over the upper surface of the first insulating layer 611A, instead, they extend merely until the upper surface of the first insulating layer 611A, while the upper surface of the first insulating layer 611A is covered by another insulating layer or dielectric layer. The function of passivation layers 612 and 613 is not only to reduce current leakage at the sidewalls, but also to passivate sidewall defects and block damage to the light-emitting mesa caused by water, oxygen, etc., during operation, they can also prevent metal diffusion from the reflective mirror layer 615, the cathode 604 etc. to the first insulating layer 611 or the first light-emitting mesa 101. The passivation layers 612 and 613 may be formed by depositing SiO₂ material using a CVD process, also may be formed by depositing Al2O3 material using an ALD process. The bottom transparent conductive layer 618 is arranged between the second epitaxial layer 601C and the reflective mirror layer 615. The bottom transparent conductive layer 618 is configured to electrically connect the second epitaxial layer 601C of the first light-emitting mesa 101 to the reflective mirror layer 615 and further to the through-hole contact portion 602. The material of the bottom transparent conductive layer 618 is, for example, metal oxide such as indium tin oxide ITO or zinc oxide ZnO, etc., its formation methods include, for example, physical vapor deposition (PVD), chemical vapor deposition (CVD), sol-gel method, solution coating method, etc.

The reflective mirror layer 615 is configured to reflect light from the first light-emitting mesa 101 upward. For this purpose, the reflective mirror layer 615 has an inclined surface on the side facing the first light-emitting mesa 101, the inclination angle of this surface is, for example, the same as the inclination angle of the light-emitting mesa, of 10° to 85°, preferably 30° to 70°, particularly 35° to 50°.

Herein, the reflective mirror layer 615 includes a side reflective mirror layer 615A, a bottom reflective mirror layer 615B and an edge portion 615C, where the side reflective mirror layer 615A and the bottom reflective mirror layer 615B constitute the main body portion of the reflective mirror layer 615. The side reflective mirror layer 615A covers at least a part of the side surface of the first light-emitting mesa 101. Both the side reflective mirror layer 615A and the bottom reflective mirror layer 615B are configured to reflect light from the first light-emitting mesa 101 upward, while the bottom reflective mirror layer 615B is also configured to electrically connect the bottom transparent conductive layer 618 with the first through-hole contact portion 602. In the present embodiment, the side reflective mirror layer 615A covers a part of the side surface of the first light-emitting mesa 101 within the recess 607, and the side reflective mirror layer 615 is formed between the passivation layer 612 and the inner wall of the recess 607 of the insulating layer. Due to the presence of the passivation layer 612, the side reflective mirror layer 615A may or may not have an atomic layer deposition layer on the side facing the first light-emitting mesa 101. In the case of having an atomic layer deposition layer, it is possible to further prevent the metal in the reflective mirror layer 615 from penetrating into the first light-emitting mesa 101 through the passivation layer 612. The side reflective mirror layer 615A has an inclined surface on the side facing the first light-emitting mesa 101 to reflect light from the light-emitting mesa upward, the inclination angle of the inclined surface is, for example, the same as the inclination angle of the first light-emitting mesa 101, of 10° to 85°, preferably 30° to 70°, and especially 35° to 50°. The bottom reflective mirror layer 615B covers at least a part of the bottom surface of the first light-emitting mesa 101. In the present embodiment, the bottom mirror 615B covers the bottom transparent conductive layer 618 of the first light-emitting mesa 101. The bottom reflective mirror layer 615B has an atomic layer deposition layer on the side facing the first light-emitting mesa 101. The atomic layer deposition layer can block metal from the reflective metal layer to prevent diffusion while substantially not affecting light reflection.

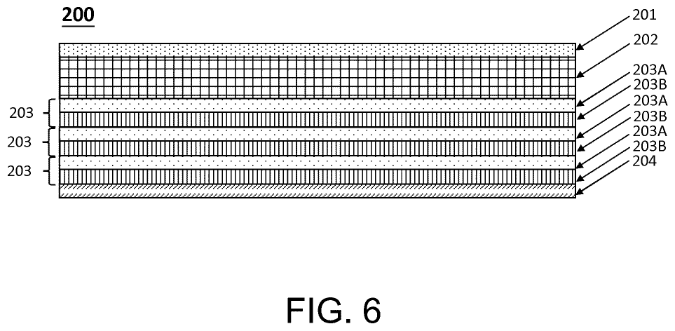

Referring to FIG. 6, the reflective mirror layer 200 includes, from top to bottom (i.e., from the side facing the first light-emitting mesa 101 to the side facing away from the first light-emitting mesa 101) an atomic layer deposition layer 201, a reflective metal layer 202, a first barrier layer 203, and a second barrier layer 204, where the upper side of the reflective mirror layer 200 faces the light-emitting mesa or epitaxial layer of the micro-LED, and the lower side of the reflective mirror layer 200 faces away from the light-emitting mesa or epitaxial layer of the micro-LED or faces the bottom transparent conductive layer.

For example, the stacked layer structure of the reflective mirror layer 615 is as follows (in an order from close to the light-emitting mesa to far away from the light-emitting mesa):
Atomic layer deposition layer 201, the material of which is nickel, the thickness is angstroms;
Reflective metal layer 202, the material of which is silver, the thickness is 1000 angstroms;
First and second barrier sublayers 203A and 203B, the materials of which are titanium and platinum, respectively, the thicknesses are 200 and 500 angstroms, respectively;
Second barrier layer 204, the material of which is titanium, the thickness is 200 angstroms.

Furthermore, the number of the first barrier layers 203 is 3.

The reflective mirror layer 615 can be formed, for example, through methods such as evaporation, sputtering, or chemical vapor deposition (CVD), etc., where the atomic layer deposition layer 201 of the reflective mirror layer 615 is formed by atomic layer deposition. The thickness of the passivation layer 612 between the reflective mirror layer 612 and the first light-emitting mesa 101 is 800 to 2000 angstroms, preferably 600 to 1600 angstroms. The thickness of the passivation layer 613 between the reflective mirror layer 615 and the inner wall of the recess 607 is 200 to 800 angstroms, preferably 300 to 600 angstroms.

As shown in FIG. 5, the passivation layer 612 of the first light-emitting mesa 101 has notches 620 on the side of the bottom transparent conductive layer 618, such that the bottom transparent conductive layer 618 can be electrically connected with the first through-hole contact portion 602 through the reflective mirror layer 615, thereby electrically connecting the second epitaxial layer 601C further to the drive circuit 606.

The dummy light-emitting mesa 102 is arranged in the non-light-emitting area NA and does not emit light. As shown in FIG. 5, the structure of the dummy light-emitting mesa 102 is basically the same as the first emitting mesa 101, i.e., also starting from the light extraction side, it includes a first epitaxial layer 601A, an emitting layer 601B, a second epitaxial layer 601C, a bottom transparent conductive layer 618, and a passivation layer 612. The difference between the structures of the dummy light-emitting mesa 102 and the first light-emitting mesa 101 lies in that, the passivation layer 612 of the dummy light-emitting mesa 102 does not have notches 620 on the side of the bottom transparent conductive layer 61, such that the second epitaxial layer 601C of the dummy light-emitting mesa 102 cannot be electrically connected to the exterior and thus cannot emit light. In the present embodiment, the dummy light-emitting mesa 102 has the same dimensions as the first light-emitting mesa 101, however, in other embodiments, the dummy light-emitting mesa 102 has different dimensions from the first light-emitting mesa 101, such as different surface heights and/or different upper surface diameters and/or different lower surface diameters and/or different spacings.

Furthermore, a reflective layer 615 is not arranged on the side of the dummy light-emitting mesa 102 facing away from the light extraction side and a first through-hole contact portion 602 is not arranged, either. Moreover, no micro-lens 605 is provided above the dummy light-emitting mesa 102. Since the dummy light-emitting mesa 102 does not need to emit light, structures such as the reflective mirror layer 615, the first through-hole contact portion 602, and the micro-lens 605 can be omitted. In other embodiments, in order to facilitate process simplification or cost reduction, one or more of the reflective mirror layer 615, the first through-hole contact portion 602, and the micro-lens 605 may also be arranged for the dummy light-emitting mesa 102. Furthermore, although a first electrode 604 is arranged for the dummy light-emitting mesa 102 in the present embodiment, in other embodiments, the first electrode 604 may not be arranged for the dummy light-emitting mesa 102.

Herein, although the dummy light-emitting mesa 102 does not emit light, due to the presence of the dummy light-emitting mesa 102, the stress, particularly shear stress on the first insulating layer 611A is significantly reduced, such that the probability of delamination, wrinkling, or voids forming between the first insulating layer 611A and the light-emitting mesa is significantly reduced, and thus the chip quality of the micro-LED 600 is improved, and the risk of failure is reduced. This is mainly because the concave-convex structure of the dummy light-emitting mesa 102 can prevent stress transmission from the non-light-emitting area NA to the light-emitting area AA, meanwhile, the area of applied force is increased by the concave-convex structure of the dummy light-emitting mesa in the non-light-emitting area NA, so that stress in the non-light-emitting area is reduced, and thus the risks of delamination, wrinkling, and void formation in the light-emitting area and the non-light-emitting area are reduced.

The top transparent conductive layer 608 is arranged on the first epitaxial layer 601A and electrically connects the first electrode 604 (cathode) with the first epitaxial layer 601A. Herein, the top transparent conductive layer 608 extends on the first epitaxial layer 601A and fully covers the first epitaxial layer 601A, thereby providing more uniform power supply for the first epitaxial layer 601A. In other embodiments, the top transparent conductive layer 608 may merely partially cover the first epitaxial layer 601A. Furthermore, the top transparent conductive layer 608 extends below the first electrode 604, which is the cathode in this case, such that the transparent conductive layer 608 extends continuously on the first epitaxial layer 601A of adjacent light-emitting mesas 601A, so that the coverage area for the first epitaxial layer 601A is increased. The material of the top transparent conductive layer 608 is, for example, metal oxide such as indium tin oxide ITO or zinc oxide ZnO, etc., and its formation methods, for example, include physical vapor deposition (PVD), chemical vapor deposition (CVD), sol-gel method, solution coating method, etc.

The first electrode 604, herein is the cathode, which is arranged to surround the first light-emitting mesa 101. The cathode 604 and its connecting components may be made of materials such as metals (such as silver, gold, or platinum), graphene, ITO, aluminum doped zinc oxide (AZO) or fluorine doped tin oxide (FTO), or any combination of the above materials. In yet another embodiment of the present invention, the cathode 604 and its connecting components may be made of non-transparent or transparent conductive materials, such as indium tin oxide (ITO). In a preferred embodiment, the cathode 604 is made of a reflective metal, so that the cathode 604 can optically isolate adjacent light-emitting mesas 601 from each other, and meanwhile also can reflect light from the light-emitting mesas 601, for example, reflecting the light upward to the microlens 605, thereby increasing light output. In another embodiment, a reflective layer, such as a silver layer, may be coated onto the surface of the cathode 604 to provide reflective capability. Herein, the surface of the cathode 604 facing the first light-emitting mesa 101A is an inclined surface, and it is inclined towards two sides (i.e. inclined from the bottom surface towards two sides), so that the light falling on it can be reflected upward, i.e. towards the light extraction side. Furthermore, the cathode 604 may be divided into an edge cathode 604A and a central cathode 604B, where the edge cathode 604A is arranged between the second electrode 610 (herein is the anode) and the outermost light-emitting mesa 601, where a part of the edge cathode 604A is arranged on the passivation layer 612, and another portion is arranged on the transparent conductive layer 608, while the central cathode 604B is arranged between adjacent light-emitting mesas 601, where the central cathode 604B is arranged on the transparent conductive layer 608. In this way, the edge cathode 604A can completely cover the side surface of the first epitaxial layer 601A and be in electrical contact with it, thereby increasing the electrical contact area between the cathode 604 and the first epitaxial layer 601A.

The first through-hole contact portion 602 is electrically connected with the bottom of the first light-emitting mesa 101 and passes through the first insulating layer 611A. The first through-hole contact portion 602 is used for hybrid bonding with the second through-hole contact portion 603, and thereby electrically connecting the bottom of the first light-emitting mesa 101, particularly the second epitaxial layer 601C to the second electrode 610 (herein is the anode). In the present embodiment, no first through-hole contact portion 602 is arranged below the dummy light-emitting mesa 102. The first through-hole contact portion 602 is preferably a cylindrical through-hole, and the inner wall and/or central space is filled with a conductor, such as metallic copper. The diameter of the first through-hole contact portion 602 is of 0.3 to 2 μm, preferably 0.6 to 1.4 μm. The first through-hole contact portion 602 may be planarized at interface A (e.g., through chemical mechanical polishing CMP) to facilitate hybrid bonding with the second through-hole contact portion 603. Furthermore, in order to enhance the bonding strength and improve the conductivity between the first through-hole contact portion 602 and the second through-hole contact portion 603, a first interface metal layer may be arranged at the first aperture of the first through-hole contact portion 602, and the area of the first interface metal layer is greater than the area of the first aperture. Similarly, a second interface metal layer may be arranged at the second aperture of the second through-hole contact portion, and the area of the second interface metal layer is greater than the area of the second aperture. The areas of the first interface metal layer and the second interface metal layer may be equal, or the area of the first interface metal layer may be greater or less than the area of the second interface metal layer. After the first interface metal layer and the second interface metal layer 202 are bonded to each other, the formed bonding surface is greater than the bonding surface formed by directly bonding the first aperture of the first through-hole contact portion 602 and the second aperture 204 of the second through-hole contact portion 603, and thus the bonding strength is enhanced and the conductivity between the first through-hole contact portion 602 and the second through-hole contact portion 603 is improved. The first interface metal layer 201 and the second interface metal layer 202 are made of, for example, a conductive metal such as copper. Their formation methods may include, for example, physical vapor deposition (PVD), chemical vapor deposition (CVD), electroplating, chemical plating, and so on. The formation method of the first through-hole contact portion 602 may be, for example, as follows: a light-emitting mesa 601 and a first insulating layer 611A are formed on a temporary substrate, then the first insulating layer 611A is etched to form through-holes leading to the bottom of the first light-emitting mesa 101, subsequently, a metal is deposited in the through-holes, and finally the apertures of the through-holes are planarized to form the bonding surface.

Furthermore, the first through-hole contact portion 602 is used to electrically connect the drive circuit 606 with the bottom (herein is the reflective mirror layer 607) of the epitaxial layer 601 (or light-emitting mesa) of the micro-LED array after bonding with the second through-hole contact portion 603, thereby connecting the epitaxial layer 601 to the anode 610. Herein, a first metal barrier layer 617 is arranged between the through-hole contact portion 602 and the reflective mirror layer 607. The first metal barrier layer 617 can prevent the metal in the first through-hole contact portion 602 from diffusing into the epitaxial layer 601 or the insulating layer 611A through the reflective mirror layer 607 and other layers (e.g., the bottom transparent electrode layer) that may be arranged therebetween, or from oxidizing. If the metal in the first through-hole contact portion 602 diffuses into the epitaxial layer 601, then the luminous performance of the epitaxial layer 601 will be affected; if it diffuses into the insulating layer 611A, then the insulating effect of the insulating layer 611A will be affected, thereby leading to leakage current or even short circuits; if the metal in the first through-hole contact portion 602 oxidizes, then it may cause poor contact between the first through-hole contact portion 602 and the reflective mirror layer 607, or even result in an open circuit in the electrical circuit to the epitaxial layer 601. From this, it can be seen that by arranging the first through-hole contact portion 602 according to the present invention, metal diffusion in the first through-hole contact portion 602 can be effectively avoided, and thus risks such as reduced luminous performance, short circuit, and open circuit of the micro-LED can be effectively prevented. The combination of the first metal barrier layer 617 and the first barrier layer 203 and the second barrier layer 204 of the reflective mirror layer can further enhance the metal barrier and antioxidant effects.

The second electrode 610, herein is the anode, is electrically connected with the drive circuit 606 through a third through-hole contact portion 614 passing through the first insulation layer 611A and the second insulation layer 611B. The anode 610 may be, for example, connected to an external power source or control source for supplying power for the micro-LED chip 600 or controlling the micro-LED chip 600. Herein, the third through-hole contact portion 614 may include a plurality of through-hole contact portions for connecting the second epitaxial layers 601C of a plurality of light-emitting mesas to the anode 610. Herein, it is exemplarily shown that the third through-hole contact portion 614 includes two through-hole contact portions, but this is merely an example, and other numbers of through-hole contact portions 614 are also conceivable. The third through-hole contact portion 614 may be formed either before hybrid bonding or after hybrid bonding. If the third through-hole contact portion 614 is formed before hybrid bonding, then the upper and lower portions of the third through-hole contact portion 614 are first formed in the upper stacked layer 600A and the lower stacked layer 600B, respectively, then after hybrid bonding, these two portions connect the through-hole contact portions on both sides, and then the first insulating layer 611A is etched from above to form the anode 610 on the third through-hole contact portion 614. If the third through-hole contact portion 614 is formed after hybrid bonding, then the first insulating layer 611A is etched from above to form through-holes leading to the drive circuit 606, metal is then deposited in the through-holes, then the third through-hole contact portion 614 is etched to form a recess, metal is then deposited in the recess to form the anode 610. The anode 610 and its connecting components may be made of materials such as metals (e.g., copper, silver, or aluminum), graphene, ITO, aluminum doped zinc oxide (AZO), or fluorine doped tin oxide (FTO), or any combination of the above materials.

The first bonding mark 609A is arranged in the first insulating layer 611A and exposes the first marking surface, i.e., the aperture of the first bonding mark. The function of the first bonding mark 609A in the upper stacked layer 600A is to serve as a mark aligned with the second bonding mark 609B in the lower stacked layer 600B, and thus precise hybrid bonding is achieved, where the second bonding mark 609B is arranged in the second insulating layer 600B and exposes the second marking surface, i.e., the aperture of the second bonding mark. The alignment method of the first bonding mark 609A with the second bonding mark 609B is to align and adhere the first marking surface with the second marking surface during hybrid bonding, at this time, the upper stacked layer 600A and the lower stacked layer 600B have been aligned, and then hybrid bonding can be performed. The first bonding mark 609A and the second bonding mark 609B may be metal through-holes, and the two may be bonded at the interface. Furthermore, the first bonding mark 609A and the second bonding mark 609B may have enlarged apertures and/or the apertures may be coated with a metal layer to facilitate identification of their positions and enhance bonding strength.

Microlens 605 is arranged above the first light-emitting mesa 101 for shaping such as focusing or collimating the light emitted therefrom. In the present embodiment, no microlens is arranged above the dummy light-emitting mesa 102. The microlens includes a lens portion 605A and a spacer portion 605B. The lens portion 605A is arranged at the outermost side, i.e. the topmost side and configured to shape light from the first light-emitting mesa 101. The spacer portion 605B is arranged between the lens portion 605A and the first light-emitting mesa 101 to adjust the focal position of the lens portion 605A, for example, parameters such as the thickness of the spacer portion 605B and the curvature of the lens portion 605A, etc. are adjusted, such that the focal point of the lens portion 605A is precisely located in the first light-emitting mesa 101 of the micro-LED. The width of the microlens 605 is, for example, 0.8 to 4 μm, preferably 1 to 3 μm. The distance between the lens portion 605A and the cathode 604 is, for example, 0.05 to 4 μm, preferably 0.1 to 0.3 μm. The microlens 605 corresponds one-to-one with the first light-emitting mesa 101. Meanwhile, in the present embodiment, adjacent microlenses 605 have gaps between them and their bottoms are connected with each other. The bottoms of the gaps are higher than the top of the first light-emitting mesa 101 or higher than the bottom of the light-emitting layer 601B of the first light-emitting mesa 101, and the lens portion 604A is located above the cathode 604. The microlens 605 may be formed through a plurality of deposition steps, during the formation process of the microlens, a SiO₂ film layer is first deposited, then ion etching is performed, and the microlens is formed at positions on the surface of the transparent conductive layer 608 corresponding to each light-emitting mesa 601.

### Lower Stacked Layer

The lower stacked layer 600B includes a second insulating layer 611B, a second through-hole contact portion 603, a drive backplane 606, and a second bonding mark 609B. The various components are described below, respectively.

The second insulating layer 611B is arranged on the drive backplane 606 and is configured to accommodate the second through-hole contact portion 603. The material of the second insulating layer 611B may be, for example, silicon dioxide, silicon nitride, high-k dielectric materials (e.g., hafnium oxide, aluminum oxide, etc.), and so on. The second insulating layer 611B may be, for example, formed on the drive backplane 606 through methods such as thermal oxidation or chemical vapor deposition (CVD), etc. The thickness of the second insulating layer 611B may be, for example, 1 to 3 μm, preferably 2 μm, and more preferably 0.6 to 1.4 μm. Furthermore, the second insulating layer 611B may be planarized at interface A (e.g., through chemical mechanical polishing CMP) to facilitate hybrid bonding with the first insulating layer 611A.

The second insulating layer 611B may be transparent to light emitted from the first light-emitting mesa 101. In some embodiments, the second insulating layer 611B is made of a dielectric material such as solid inorganic material or plastic material. In some embodiments, the solid inorganic material includes silicon dioxide (SiO₂), aluminum oxide (Al₂O₃), silicon nitride (Si₃N₄), silicon carbide nitride (SiCN), hafnium oxide (HfO₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof. In some embodiments, the plastic material includes polymers such as SU-8, PermiNex, or benzocyclobutene (BCB), or transparent plastics (resins) including spin-on glass (SOG), or adhesive micro resist BCL-1200, or any combination thereof. In some embodiments, the second insulating layer 611B may facilitate the passage of light emitted from the first light-emitting mesa 101. In some embodiments, the second insulating layer 611B may include a plurality of portions, such as three embedded dielectric portions and two adhering dielectric portions. The embedded dielectric portions refer to the dielectric layers surrounding each light-emitting diode structure; while the adhering dielectric portions refer to the dielectric layers between two light-emitting diode structures. The embedded dielectric portions and the adhering dielectric portions may have the same or different compositions.

The second through-hole contact portion 603, which passes through the second insulating layer 611B. The second through-hole contact portion 603 is configured to hybrid bond with the first through-hole contact portion 602 at interface A, and thereby electrically connecting the bottom of the first light-emitting mesa 101, particularly the second epitaxial layer 601C to the second electrode 610 (herein is the anode). The second through-hole contact portion 603 is preferably a cylindrical through-hole, and the inner wall and/or central space is filled with a conductor, such as metallic copper. The diameter of the second through-hole contact portion 603 is of 0.5 to 2.2 μm, preferably 0.8 to 1.6 μm. The second through-hole contact portion 603 may be planarized at interface A (e.g., through chemical mechanical polishing CMP) to facilitate hybrid bonding with the first through-hole contact portion 602. Furthermore, in order to enhance the bonding strength and improve the conductivity between the second through-hole contact portion 603 and the first through-hole contact portion 602, a second interface metal layer may be arranged at the second aperture of the second through-hole contact portion 603, and the area of the second interface metal layer is greater than the area of the second aperture. Similarly, a first interface metal layer may be arranged at the first aperture of the first through-hole contact portion 602, and the area of the first interface metal layer is greater than the area of the first aperture. The areas of the first interface metal layer and the second interface metal layer may be equal, or the area of the first interface metal layer may be greater or less than the area of the second interface metal layer. After the first interface metal layer and the second interface metal layer are bonded to each other, the formed bonding surface is greater than the bonding surface formed by directly bonding the first aperture of the first through-hole contact portion 602 and the second aperture of the second through-hole contact portion 603, and thus the bonding strength is enhanced and the conductivity between the first through-hole contact portion 602 and the second through-hole contact portion 603 is improved. The first interface metal layer and the second interface metal layer are made of, for example, a conductive metal such as copper. Their formation methods may include, for example, physical vapor deposition (PVD), chemical vapor deposition (CVD), electroplating, chemical plating, and so on. The formation method of the second through-hole contact portion 603 may be, for example, as follows: a drive backplane 606 is provided, then a second insulating layer 611B is formed on the drive backplane 606, then the second insulating layer 611B is etched to form through-holes leading to the top of the drive backplane 606, subsequently, a metal is deposited in the through-holes, and finally the apertures of the through-holes are planarized to form the bonding surface.

Furthermore, the second through-hole contact portion 603 is used to electrically connect the drive circuit 606 with the bottom (herein is the reflective mirror layer 607) of the epitaxial layer 601 (or light-emitting mesa) of the micro-LED array after bonding with the first through-hole contact portion 602, thereby connecting the epitaxial layer 601 to the anode 610. Herein, a first metal barrier layer 617 is arranged between the second through-hole contact portion 603 and the drive circuit 606. The first metal barrier layer 617 can prevent the metal in the second through-hole contact portion 603 from diffusing into the drive circuit 606 or the insulating layer 611B, or from oxidizing. If the metal in the second through-hole contact portion 603 diffuses into the drive circuit 606, then the electrical performance of the drive circuit will be affected, such as causing a short circuit; if it diffuses into the insulating layer 611B, then the insulating effect of the insulating layer 611B will be affected, thereby leading to leakage current or even short circuits; if the metal in the second through-hole contact portion 603 oxidizes, then it may cause poor contact between the second through-hole contact portion 603 and the drive circuit 606, or even result in an open circuit in the electrical circuit to the drive circuit 606. From this, it can be seen that by arranging the second through-hole contact portion 603 according to the present invention, metal diffusion in the second through-hole contact portion 603 can be effectively avoided, and thus risks such as short circuits or open circuits in the drive circuit 606 can be effectively avoided. The combination of the first metal barrier layer 617 and the first barrier layer 203 and the second barrier layer 204 of the reflective mirror layer can further enhance the metal barrier and antioxidant effects.

The drive backplane 606 (or drive circuit) is electrically connected with the second through-hole contact portion 603 to electrically connect the second epitaxial layer 601C of the first light-emitting mesa 101 to the anode 610. For this purpose, the drive backplane 606 has conductive line layers for interconnecting each second through-hole contact portion 603 to the corresponding anode 610. The drive backplane 606 may be, for example, a thin-film transistor TFT drive circuit and may include 2T1C drive circuit, 3T1C drive circuit, and 5T2C drive circuit. The drive backplane 606 is configured to drive the micro-LEDs, such as controlling the switching on/off and brightness of the micro-LEDs. The drive backplane 606 may include, for example, transistors, capacitors, a conductive line layer, an insulating layer, and a metal layer, etc. The conductive line layer is formed on the substrate and configured to supply power to the micro-LED array. The insulating layer is formed on the conductive line layer, where through-holes are arranged in the insulating layer, and through-hole contact portions (e.g., IC copper pillars) are arranged in the through-holes for electrically connecting the conductive line layer with the micro-LED array. The metal layer is used for bonding and electrically contacting the micro-LEDs. The conductive line layer, the metal layer, and the insulating layer may be formed on substrate 601 through deposition methods such as physical vapor deposition (PVD) and chemical vapor deposition (CVD).

The second bonding mark 609B is arranged in the second insulating layer 611B and exposes the second marking surface, i.e., the aperture of the second bonding mark. The function of the second bonding mark 609B in the lower stacked layer 600B is to serve as a mark aligned with the first bonding mark 609A in the upper stacked layer 600A, and thus precise hybrid bonding is achieved. The alignment method of the first bonding mark 609A with the second bonding mark 609B is to align and adhere the first marking surface with the second marking surface during hybrid bonding, at this time, the upper stacked layer 600A and the lower stacked layer 600B have been aligned, and then hybrid bonding can be performed. The first bonding mark 609A and the second bonding mark 609B may be metal through-holes, and the two may be bonded at the interface. Furthermore, the first bonding mark 609A and the second bonding mark 609B may have enlarged apertures and/or the apertures may be coated with a metal layer to facilitate identification of their positions and enhance bonding strength.

After the formation of the lower stacked layer 600A and the upper stacked layer 600B, the lower stacked layer 600A is jointed with the upper stacked layer 600B through hybrid bonding, such that the first through-hole contact portion 602 is bonded with the second through-hole contact portion 603 and the first insulating layer 611A is bonded with the second insulating layer 611B, optionally the first bonding mark 609A is bonded with the second bonding mark 609B, and the upper and lower portions of the third through-hole contact portion 614 are bonded with each other. The present invention solves the technical problem encountered in manufacturing upside-down arranged trapezoidal light-emitting mesa with a large upper surface and a small lower surface, i.e., the electrical connection problem of the light-emitting mesa to the driving circuit, by respectively fabricating the upper stacked layer 600A and the lower stacked layer 600B and then jointing them with each other through hybrid bonding. The present invention achieves electrical connection of the first light-emitting mesa 101 to the drive circuit 606 through hybrid bonding, allowing both the upper stacked layer 600A and the lower stacked layer 600B can be manufactured from the surface opposed to the hybrid bonding surface, i.e., interface A, towards the hybrid bonding surface, so that high-quality conductive structures, such as the first to third through-hole contact portions (such as IC copper pillars) are achieved, and the length of the conductive structure can also be flexibly selected.

An exemplary of the hybrid bonding may include the following two parts:
(1) Dielectric-to-dielectric bonding (i.e., bonding between the first insulating layer 611A and the second insulating layer 611B): at room temperature, extremely flat and smooth dielectric surfaces obtained through chemical mechanical polishing (CMP) are brought into close contact at room temperature after activation through methods such as plasma treatment to achieve preliminary bonding.
(2) Metal-to-metal bonding (i.e., bonding between through-hole contact portions): after completing the dielectric-to-dielectric bonding, the upper and lower stacked layers are heated to 200-400° C. for annealing treatment to strengthen the dielectric bonding and promote metal-to-metal bonding, thereby achieving hybrid bonding.

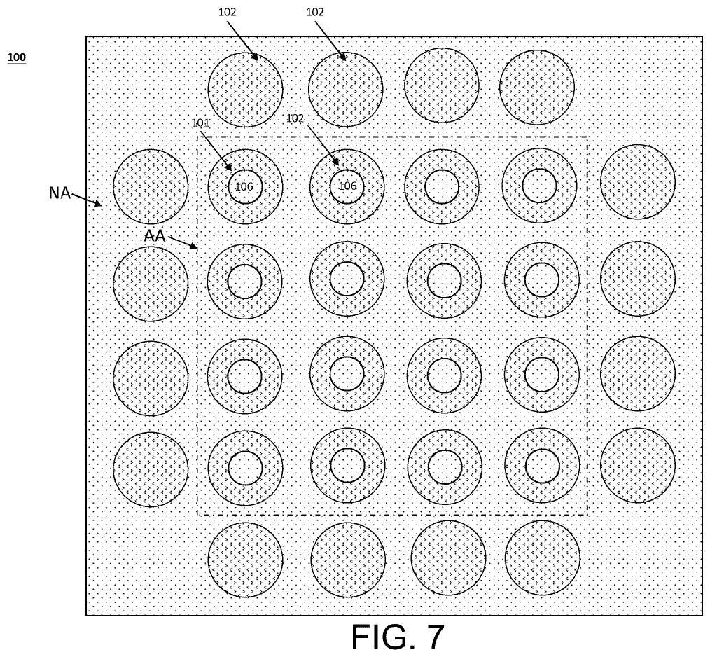

FIG. 7 illustrates a top view schematic diagram of an epitaxial wafer according to the present invention.

As shown in FIG. 7, a part of the light-emitting mesas on the epitaxial wafer 100 are first light-emitting mesas 101, which have notches 106, and the notches 106 expose the bottom transparent conductive layer on the top of the first light-emitting mesa 101 for subsequent electrical connection; another part of the light-emitting mesas on the epitaxial wafer 100 are dummy light-emitting mesas 102, whose top surface does not have a notch 106. In this example, the non-light-emitting area NA surrounds the light-emitting area AA. In other embodiments, the non-light-emitting area NA may also merely partially surround the light-emitting area AA or merely adjacent to the light-emitting area AA.

Although some embodiments of the present invention have been described in the present application, however, those skilled in the art will appreciate that these embodiments are merely illustrated as examples. Numerous variation schemes, alternative schemes, and improvement schemes may be conceived by those skilled in the art in light of the teachings of the present invention without departing from the scope of the present invention. The appended claims are intended to define the scope of the present invention and thus encompass methods and structures within the scope of these claims themselves and their equivalent variations.

What is claimed is:

1. A micro-LED with a dummy light-emitting mesa, comprising:
a plurality of light-emitting mesas, each light-emitting mesa comprising:
a bottom transparent conductive layer;
a light-emitting layer; and
a first epitaxial layer arranged between the bottom transparent conductive layer and the light-emitting layer;
a second epitaxial layer arranged on the light-emitting layer, wherein the light-emitting layer is arranged between the first epitaxial layer and the second epitaxial layer and configured to emit light, and an area of an upper surface of the light-emitting mesa close to the second epitaxial layer is greater than an area of a lower surface close to the first epitaxial layer; and
a passivation layer covering a lower surface and a side surface of the light-emitting mesa, wherein the light-emitting mesa comprises at least one first light-emitting mesa and at least one dummy light-emitting mesa, wherein the passivation layer on the at least one first light-emitting mesa has at least one notch to expose the bottom transparent conductive layer, and the passivation layer on the at least one dummy light-emitting mesa has no notch.

2. The micro-LED according to claim 1, wherein:
a depth of the dummy light-emitting mesa is different from a depth of the first light-emitting mesa; and/or
a diameter of the upper surface of the dummy light-emitting mesa is different from a diameter of the upper surface of the first light-emitting mesa; and/or
a diameter of the lower surface of the dummy light-emitting mesa is different from a diameter of the lower surface of the first light-emitting mesa; and/or
a spacing between the dummy light-emitting mesas is different from a spacing between the first light-emitting mesas.

3. The micro-LED according to claim 1, wherein:
the depth of the dummy light-emitting mesa is the same as the depth of the first light-emitting mesa; and/or
a diameter of the upper surface of the dummy light-emitting mesa is the same as a diameter of the upper surface of the first light-emitting mesa; and/or
a diameter of the lower surface of the dummy light-emitting mesa is the same as a diameter of the lower surface of the first light-emitting mesa; and/or
a spacing between the dummy light-emitting mesas is the same as a spacing between the first light-emitting mesas.

4. The micro-LED according to claim 3, further comprising a buffer layer, wherein:
a thickness of the buffer layer is 4000 to 8000 angstroms; and/or
a thickness of the first epitaxial layer is 2500 to 3500 angstroms; and/or
a thickness of the light-emitting layer is 2000 to 4000 angstroms; and/or
a thickness of the second epitaxial layer is 4000 to 5000 angstroms; and/or
a thickness of the bottom transparent conductive layer is 800 to 1500 μm; and/or
a thickness of the passivation layer is 800 angstroms to 1800 angstroms.

5. The micro-LED according to claim 1, wherein a number of dummy light-emitting mesas accounts for 40% to 50% of a total number of light-emitting mesas.

6. The micro-LED according to claim 1, wherein:
a diameter of the lower surface of the light-emitting mesa is 0.8 to 1.2 μm; and/or
a diameter of the upper surface of the light-emitting mesa is 1.4 to 1.8 μm; and/or
a height of the light-emitting mesa is 0.3 to 0.7 μm.

7. The micro-LED according to claim 1, wherein the second epitaxial layer comprises:
a step portion, which is in electrical contact with the light-emitting layer; and
a base portion extending from the step portion toward two sides of the step portion.

8. The micro-LED according to claim 7, wherein:
a thickness of the step portion is: 400 nm to 800 nm; and/or
a thickness of the base portion is 4 to 4.4 μm.

9. The micro-LED according to claim 1, further comprising:
a reflective mirror layer arranged to surround the first light-emitting mesa;
at least one drive circuit having a metal layer, a plurality of through-hole contact portions are arranged on the at least one drive circuit, wherein the plurality of through-hole contact portions are electrically connected with the metal layer, and an area of the micro-LED array is bonded onto the drive circuit through a bottom conductive bonding layer, wherein the at least one drive circuit further comprises a wiring stacked layer below the metal layer, the wiring stacked layer configured to lead out a first electrode;
an insulating layer configured to accommodate the first light-emitting mesa, the dummy light-emitting mesa, and the plurality of through-hole contact portions;
a first electrode electrically connected with the plurality of through-hole contact portions;
a top transparent conductive layer arranged on the surface of the passivation layer and in electrical contact with the second epitaxial layer; and
a second electrode arranged on the surface of the top transparent conductive layer.

10. A micro-LED chip with a dummy light-emitting mesa, comprising:
a light-emitting area comprising a plurality of first light-emitting mesas, the first light-emitting mesas configured to emit light; and
a non-light-emitting area adjacent to the light-emitting area and comprising a plurality of dummy light-emitting mesas, the dummy light-emitting mesas configured to not emit light.

11. The micro-LED chip according to claim 10, wherein:
a proportion of the light-emitting area in the micro-LED chip is 50% to 60%; and/or
a proportion of non-light-emitting area in the micro-LED chip is 40% to 50%.

12. The micro-LED chip according to claim 10, wherein both the first light-emitting mesa and the dummy light-emitting mesa comprise:
a bottom transparent conductive layer facing the light extraction side;
a light-emitting layer;
a first epitaxial layer arranged between the bottom transparent conductive layer and the light-emitting layer; and
a second epitaxial layer facing away from the light extraction side, wherein the light-emitting layer is arranged between the first epitaxial layer and the second epitaxial layer and configured to emit light, and an area of the upper surface of the light-emitting mesa facing the light extraction side is greater than the area of the lower surface facing away from the light extraction side.

13. The micro-LED chip according to claim 10, wherein:
a diameter of the lower surface of the first light-emitting mesa is 0.8 to 1.2 μm; and/or
a diameter of the upper surface of the first light-emitting mesa is 1.4 to 1.8 μm; and/or
a height of the first light-emitting mesa is 0.3 to 0.7 μm.

14. The micro-LED chip according to claim 10, wherein:
the light-emitting area further comprises through-hole contact portions, which are configured to electrically connect the second epitaxial layer of the first light-emitting mesa to the first electrode; and
the non-light-emitting area does not have through-hole contact portions for electrically connecting the second epitaxial layer of the dummy light-emitting mesa to the drive circuit.

15. The micro-LED chip according to claim 14, wherein:
the light-emitting area further comprises a top transparent conductive layer, which is arranged on an upper surface of the light-emitting mesa to electrically connect the first epitaxial layer to the second electrode; and
the non-light-emitting area does not have the top transparent conductive layer.

16. The micro-LED chip according to claim 15, further comprising:
a passivation layer covering a lower surface of the first light-emitting mesa and a lower surface of the dummy light-emitting mesa, wherein the passivation layer on the first light-emitting mesa has notches to expose the bottom transparent conductive layer, and the passivation layer on the dummy light-emitting mesa has no notch.

17. The micro-LED chip according to claim 15, further comprising:
a reflective mirror layer arranged to surround the first light-emitting mesa and configured to reflect light emitted from the first light-emitting mesa toward the light extraction side;
at least one drive circuit having a metal layer, a plurality of through-hole contact portions are arranged on the at least one drive circuit, and wherein the plurality of through-hole contact portions are electrically connected with the metal layer, and an area of the micro-LED array is bonded onto the drive circuit through a bottom conductive bonding layer, wherein the at least one drive circuit further comprises a wiring stacked layer below the metal layer, the wiring stacked layer is configured to lead out a first electrode;
an insulating layer configured to accommodate the first light-emitting mesa, the dummy light-emitting mesa, and the plurality of through-hole contact portions;
a first electrode electrically connected with the plurality of through-hole contact portions;
a top transparent conductive layer arranged on the surface of the passivation layer and in electrical contact with the second epitaxial layer; and
a second electrode arranged on the surface of the top transparent conductive layer.

18. The micro-LED chip according to claim 17, wherein the passivation layer is a Si₃N₄ film, a SiO₂ film, or an Al₂O₃ film.

19. The micro-LED chip according to claim 17, wherein:
the material of the insulating layer is selected from one or more of the following: silicon dioxide (SiO₂), aluminum oxide (Al₂O₃), silicon nitride (Si₃N₄), silicon carbide nitride (SiCN), hafnium oxide (HfO₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof; and/or
the material of the metal layer is selected from one or more of the following: aluminum (Al), copper (Cu), tungsten (W), silver (Ag), gold (Au), nickel (Ni), platinum (Pt), tantalum (Ta), and molybdenum (Mo).

20. The micro-LED chip according to claim 17, wherein the through-hole contact portions comprise a first and a second through-hole contact portions, and the insulating layers comprise a first and a second insulating layers, and the micro-LED chip comprises an upper stacked layer and a lower stacked layer, wherein the upper stacked layer comprises the first insulating layer, the light-emitting mesa, and the first through-hole contact portion, and the lower stacked layer comprises the second insulating layer, the second through-hole contact portion, and the drive circuit, wherein the lower stacked layer is jointed with the upper stacked layer through hybrid bonding, such that the first through-hole contact portion is bonded with the second through-hole contact portion, and the first insulating layer is bonded with the second insulating layer.
